(19) United States
(12) Patent Application Publication
(10) Pub. No.: US 2013/0103330 A1
(43) Pub. Date: Apr. 25, 2013

(54) Phase-Level Power Management in an Information Technology Facility

(71) Applicants: Timothy J. Cox, Oak Point, TX (US); Brian D. Koblenz, Seattle, WA (US); Michael J. Lavazza, San Jose, CA (US)

(72) Inventors: Timothy J. Cox, Oak Point, TX (US); Brian D. Koblenz, Seattle, WA (US); Michael J. Lavazza, San Jose, CA (US)

(73) Assignee: CISCO TECHNOLOGY, INC., San Jose, CA (US)

(21) Appl. No.: 13/297,365

(22) Filed: Nov. 16, 2011

Related U.S. Application Data
(60) Provisional application No. 61/548,813, filed on Oct. 19, 2011.

(51) Int. Cl. G06F 19/00; G01R 19/00

(52) U.S. Cl. 702/60; 324/107

(57) ABSTRACT

Techniques are provided for managing the infrastructure (power distribution chain) of an information technology (IT) facility, sometimes referred to herein as a data center, comprising hierarchically arranged low-level and higher level components. This power distribution chain management occurs at the phase-level (i.e., at each of the phases of power that are utilized in the power distribution chain). In one example, characteristics representing the consumption of power of one or more of the low-level components are obtained. Based on the obtained characteristics, the power consumption for each of a plurality of the higher-level components is determined. Based on the power consumption determined for each of the plurality of higher-level components, a global power consumption, at the phase-level, for the entire power distribution chain is determined at the one or more low-level components.

### CROSS-REFERENCE TO RELATED APPLICATIONS

This application claims the benefit of U.S. Provisional Patent Application No. 61/548,813 filed on Oct. 19, 2011. The content of this provisional application is hereby incorporated by reference herein.

### TECHNICAL FIELD

The present disclosure relates to managing the infrastructure of an information technology (IT) facility.

### BACKGROUND

In three-phase electric power distribution, three conductors each carry one of three alternating currents. The three alternating currents have the same frequency, but reach their instantaneous peak values at different times. When one conductor is viewed as the reference, the currents on the other two conductors are delayed in time by one-third and two-thirds of one cycle, respectively. The three phases are generally referred to as phase L₁ or phase A (the first phase), phase L₂ or phase B (the second phase), and phase L₃ or phase C (the third phase).

Three-phase power is generally used to distribute power to the equipment in an information technology (IT) facility, sometimes referred to herein as data center. The equipment in a data center may include, for example, computers, servers, networking devices (e.g., switches, routers, firewalls, load balancers), storage systems, environment controls (e.g., air conditioning, fire suppression), security devices, etc.

### BRIEF DESCRIPTION OF THE DRAWINGS

FIG. 1A is a schematic diagram of a section of a data center managed through infrastructure management techniques described herein.

FIG. 1B is a schematic diagram of a larger section of the data center of FIG. 1A managed through the example infrastructure management techniques.

FIG. 2 is a graph generated based on analyzed characteristics representing the power consumption in a power distribution chain.

FIG. 3 is a flowchart of an example method implemented in accordance with infrastructure management techniques described herein.

FIG. 4 is a flowchart of a method implemented during determination of the global power consumption of components in a power distribution chain.

FIG. 5 is a method for performing a power distribution unit (PDU) phase amperage draw and power consumption update

FIGS. 6A-6B collectively illustrate a flowchart of a method for performing a power chain component phase amperage draw and power consumption update.

FIGS. 7-18 are screen shots of an example Data Center Infrastructure Management (DCIM) application for use in managing a data center.

FIG. 19 is a schematic diagram of a PDU implemented in accordance with techniques described herein.

FIGS. 20-32 are additional screen shots of the example DCIM application for use in managing the data center.

### DESCRIPTION OF EXAMPLE EMBODIMENTS

### Overview

Techniques are provided for managing the infrastructure (power distribution chain) of an information technology (IT) facility, sometimes referred to herein as a data center, comprising hierarchically arranged low-level and higher level components. This power distribution chain management occurs at the phase-level (i.e., at each of the phases of power that are utilized in the power distribution chain). In one example, characteristics representing the consumption of power, at a phase-level, of one or more of the low-level components are obtained. Based on the obtained characteristics, the power consumption, at the phase-level, for each of a plurality of the higher-level components is determined. Based on the power consumption determined for each of the plurality of higher-level components, a global power consumption, at the phase-level, for the entire power distribution chain is determined at the one or more low-level components.

### Example Embodiments

Three-phase power is generally used to distribute power to the equipment (computers, servers, networking devices, storage systems, environment controls, security devices, etc.) in a data center. However, in certain circumstances, the three-phase power may be consumed by the equipment in an unbalanced fashion across the three different phases. That is, the equipment may be configured in the data center such that a relatively larger amount of power is consumed on one of the phases, while a relatively smaller amount of power is consumed on another phase. This phase imbalance may cause the data center resources (power, space, equipment, port connectivity, etc.) to become stranded and unusable. Stranded resources may cause significant degradation of the data center's return on investment (ROI).

Current practices used by facility and IT personnel to balance power consumption are to deploy equipment, measure consumption after the deployment, and, when there is a problem, remediate. In most cases, such measurements are labor intensive, do not represent a coherent snapshot of the data center, and are not made in real time. It can take weeks/months to understand the impact introduced by recent equipment deployments. Measurements are normally realized through the use of systems (e.g., building automation systems (BAS)) owned by the facility organization. These facility measurements are provided to the IT organization which then analyzes the data. Based on the analysis, past deployments may be remediated. Other conventional solutions are capable of monitoring only historical consumption of power. These systems currently do not have the ability to forecast or propagate various future loads or phase-balance characteristics for electrical power distribution systems. Furthermore, use of a limited number of temporary current transformers typically gives rise to measurements at different points in time, where the data center, may in fact be operating differently, thereby obfuscating a coherent view of the actual information. The conventional systems may provide visibility towards consumption, but do not enable proactive determination of the effects of future deployments and how these deployments should be executed.

Lack of real-time visibility of planned and actual power consumption resolutions at every component in the power distribution chain causes data center implementation to be executed a first time (to deploy) and re-executed to remediate and balance consumption. This rework results in higher costs and elevated risks to data center owners and clients who utilize the facility to host their applications.

A power distribution chain/infrastructure management application and associated infrastructure management techniques are described herein for guiding the IT system administrator in balancing power (i.e., one, two or three-phase power) consumption at the phase-level. That is, the disclosed techniques enable the balancing of power within the data center across the different phases utilized in the power distribution chain. The disclosed techniques are configured to obtain real-time measurements that enable the balancing at the planning, implementation, and operation stages of a data center's lifecycle. Enabling phase balancing, particularly at the planning stage of the data center lifecycle, reduces costs that span multiple organizations (facility and IT) by substantially eliminating costly rework resulting from remediation. Because remediation is substantially eliminated, the risk of overload and stranded resources is substantially eliminated and the number of interactions between the facility and IT organizations is reduced. As described below, example infrastructure management techniques may take into account both planned (projected) and actual power consumption, down to the phase resolution.

As described further below, a power distribution chain used in a data center comprises a plurality of hierarchically arranged components. In the hierarchical arrangement, the components in the power distribution china are “above,” “below,” or “at the same level as” one another. Examples of the infrastructure management techniques described herein allow power consumption characteristics to be obtained at one or more “low-level” components (i.e., components at or near the end of the power distribution chain that provide power to equipment in the data center). These obtained characteristics may then be used to determine the power consumption (actual, maximum, projected, etc.) for “higher-level” components (i.e., components between the low-level components and the utility power feeds). Once the power consumption for the higher-level components is generated, a global power consumption view (i.e., a view of the power consumption of the whole data center) may be determined at the low-level components, and thus be used to make local decisions. In certain circumstances, these techniques may be used at the planning stages and, by being able to propagate a plan before it is implemented; the techniques may actually avoid a data center outage that could have occurred because a limit was reached many levels up the power distribution chain.

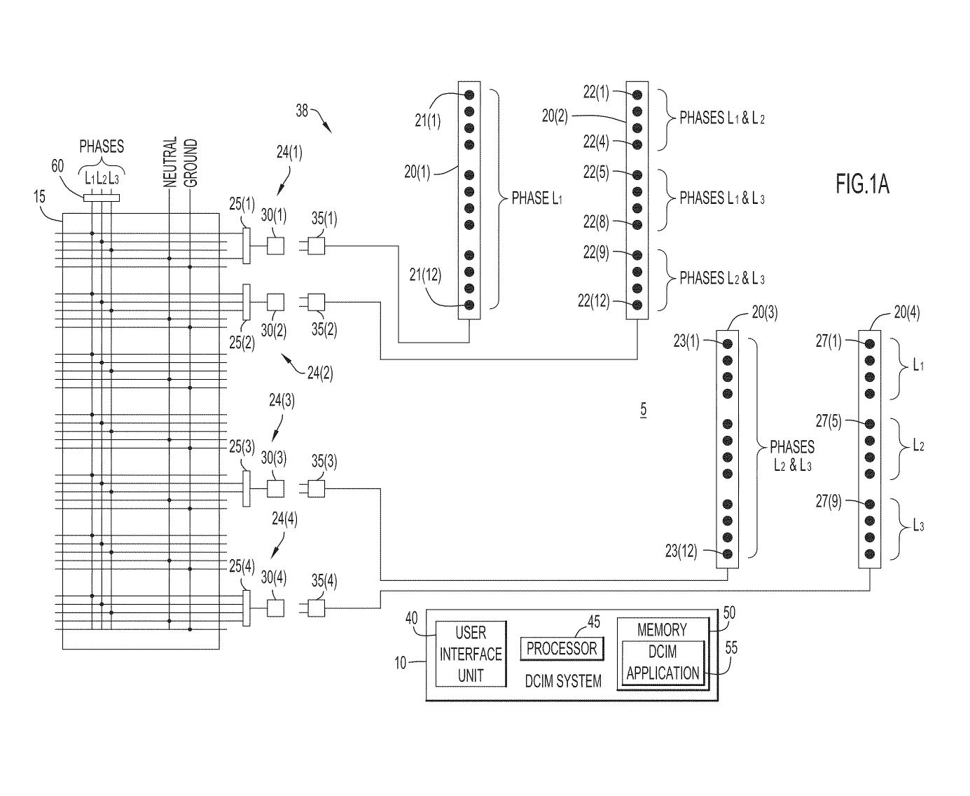

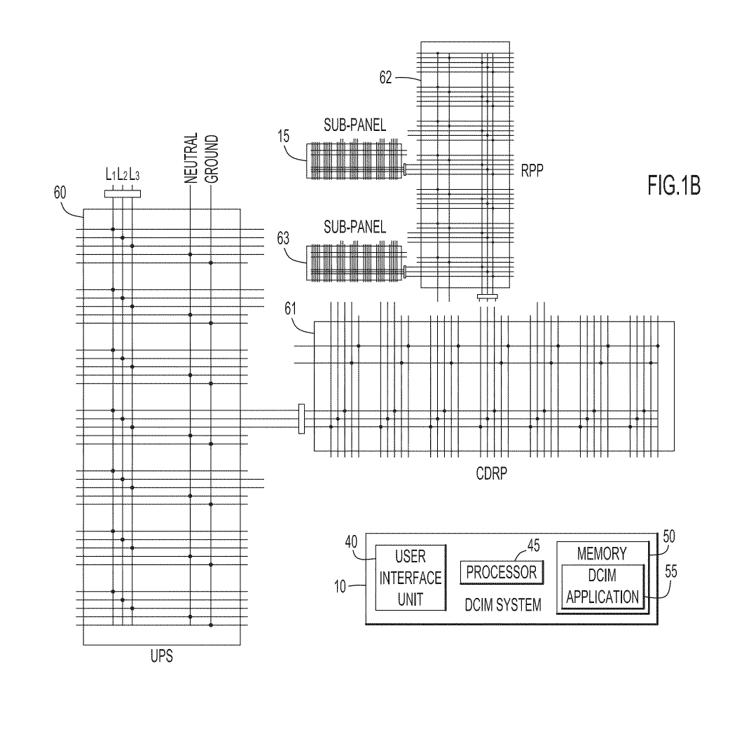

FIG. 1A is a schematic diagram of a section of a data center 5 that is managed through the use of an infrastructure management system, shown as Data Center Infrastructure Management (DCIM) system 10. DCIM system 10 comprises a user interface unit 40, processor 45, and a memory 50 that includes DCIM application 55. The illustrated portion of data center 5 comprises a sub-panel 15 and a plurality of power distribution units (PDUs) 20(1)-20(4). PDU 20(1) comprises twelve sockets 21(1)-21(12), PDU 20(2) comprises twelve sockets 22(1)-22(12), PDU 20(3) comprises twelve sockets 23(1)-22(12), and PDU 20(4) comprises twelve sockets 27(1)-27(12). Each PDU 20(1)-20(4) is electrically connected to sub-panel 15 by a whip 24(1)-24(4), respectively. Whips 24(1)-24(4) comprise a breaker 25(1)-25(4), respectively, and an outlet 30(1)-30(4), respectively, connected to the breaker. A plug 35(1)-35(4), respectively, coupled to each of the PDUs 20(1)-20(4) mates with outlets 30(1)-30(4), respectively.

It is to be appreciated that the arrangement of FIG. 1A is merely illustrative, and that other arrangements (such as other wiring arrangements) may be implemented. For example, with no loss of generality, it would be possible to hardwire to terminal blocks instead of using plugs and receptacles.

Sub-panel 15 receives three-phase power (phases L₁, L₂, and L₃) via breaker 60, and then distributes the power to PDUs 20(1)-20(4). In this example, PDU 20(1) receives only phase L₁, and distributes phase L₁ via all of its sockets 21(1)-21(12). In contrast, PDU 20(2) receives all three phases L₁, L₂, and L₃, and distributes the phases via its sockets 22(1)-22(12) in different combinations. More specifically, sockets 22(1) through 22(4) distribute phases L₁ & L₂, sockets 22(5) through 22(8) distribute phases L₁ & L₃, while sockets 22(9) through 22(12) distribute phases L₂ & L₃. PDU 20(3) receives phases L₂ & L₃, and distributes these phases via all of its sockets 23(1)-23(12). PDU 20(4) receives all three phases L₁, L₂, and L₃, and distributes each of these phases separately. More specifically, sockets 27(1)-27(4) distribute phase L₁ (i.e., the sockets are coupled to L₁ and neutral), sockets 27(5)-27(8) distribute phase L₂ (i.e., the sockets are coupled to L₂ and neutral), and sockets 27(9)-27(12) distribute phase L₃ (i.e., the sockets are coupled to L₃ and neutral).

Data center 5 includes a power distribution chain (infrastructure) 38 that is used to provide power to IT equipment in the data center. In the illustrative arrangement of FIG. 1, the components in the facility power distribution chain are sub-panel 15 (with associated breaker 60) and whips 24(1)-24(4) (with associated breakers 25(1)-25(4), respectively), and PDUs 20(1)-20(4) deployed into data center cabinets (not shown in FIG. 1. As would be appreciated, the facility power distribution chain includes additional, higher-level components that connect sub-panel 15 to the utility feeds that are fed into data center 5. These components may include, for example, additional sub-panels, remote panels, uninterruptible power supplies (UPSs), or other power distribution components. FIG. 1B is a example of a larger section of data center 5 including a USP 60, and additional distribution panels 61, 62, and 63. Therefore, in general, the top of the power distribution chain is fed by the utility feeds coming into the data center, and the bottom of the power distribution chain is connected to equipment deployed in the data center.

It is to be appreciated that the power distribution chain may take a number of different arrangements. For example, in certain circumstances, the PDUs can be midpoints in the power distribution chain (e.g., a PDU could plug into another PDU). Also, in the presence of “dumb” PDUs, it would be possible to have an IT device reporting the power used by the socket. In such arrangements, the infrastructure management techniques described herein would still be able to propagate the power consumption up and down the power chain.

Power distribution chains have parent child relationships. Components in the chain can be both a parent to one component and a child to another component. Components at the top of the chain (highest-level components) do not have parents, while components at the bottom of the chain (lowest-level components) do not have children components. The following is a textual representation of a fictitious facility power distribution chain, referred to as power distribution chain 1. As shown, power distribution chain 1 is three levels deep with two children at each sub-level.

### Power Distribution Chain 1

### Component A (Level 1)

### Component B-1 (Level 2)

### Component C-1 (Level 3)

### Component C-2 (Level 3)

### Component B-2 (Level 2)

### Component C-3 (Level 3)

### Component C-4 (Level 3)

Each component in power distribution chain 38 has a maximum load that the component can sustain prior to failure. Three-phase components (i.e., components designed to distribute all three-phases of power) not only have a maximum load capability at the component, but there is also a maximum load capability for each phase distributed through the component. Component ratings are generally provided with amperage draws that define when the component will fail. A component's rating may be provided for an infinite duration, or may be provided for a limited period of time. Components rated for limited periods of time are, in practice, derated.

With reference to the example of FIG. 1, sub-panel 15 is associated with breaker 60 which is rated to 225 amperes (Amps) and is a three pole breaker (i.e., breaker 60 is configured to handle all three power phases L₁, L₂, and L₃). Breaker 60 is also derated to 180 Amps for continuous operation (i.e., 225 Amps×80%). As such, the maximum derated load (assuming 208V phase-phase voltage) is 64.8 kW (i.e., 180 Amps×208 Volts*√3/1000), which is evenly divided over the three phases L₁, L₂, and L₃ (i.e., 21.6 kW continuous load for phase L₁, 21.6 kW continuous load for phase L₂, and 21.6 kW continuous load for phase L₃).

Whip 24(1) of FIG. 1 is associated with breaker 25(1), which is rated to 20 Amps and is a single pole breaker (i.e., breaker 25(1) is configured to handle only one phase). Breaker 25(1) is derated to 16 Amp at continuous draw and has a maximum derated load of 1.920 kW. Since whip 24(1) is connected to PDU 20(1) which only distributes phase L₁, all of the power through breaker 25(1) is on phase L₁. Whip 24(2) is associated with breaker 25(2), which is rated to 60 Amps and is a three pole breaker. Breaker 25(2) is derated to 48 Amp at continuous draw and has a maximum derated load of 17.292 kW. Since whip 24(2) is connected to PDU 20(2) which distributes phases L₁, L₂, and L₃, a maximum load would be evenly divided over the three phases L₁, L₂ and L₃ (i.e., 5.764 kW continuous load for phase L₁, 5.764 kW continuous load for phase L₂, and 5.764 kW continuous load for phase L₃). Whip 24(3) is associated with breaker 25(3) which is rated to 30 Amps, and is a two pole breaker. Breaker 25(3) is derated to 24 Amp at continuous draw, and has a maximum load of 4.992 kW. Since whip 24(3) is connected to PDU 20(3) which distributes phases L₂ and L₃, a maximum load would be evenly divided over the two phases L₂ and L₃ (i.e., 2.496 kW continuous load for phase L₂ and 2.496 kW continuous load for phase L₃).

As noted above, power distribution chain 38 comprises PDUs 20(1)-20(4). PDUs may have a number of different names, such as Cabinet Distribution Units (CDU), Intelligent Power Strips, etc. In general, PDUs 20(1)-20(4) are devices deployed in a cabinet used to distribute power and are configured to meter characteristics or attributes (power consumption, temperatures, humidity, etc.) that are local to a cabinet. As noted above, PDUs 20(1)-20(4) are connected to the higher-level components in the power distribution chain 38 via whips 24(1)-24(4), respectively, and include the sockets to which the equipment in the facility is connected. PDUs 20(1)-20(4) may be network enabled and allow the information they meter to be retrieved over a network and utilized by the DCIM application/system described below. Each PDU 20(1)-20(4) provides many sockets for connection to equipment. Generally, one PDU will include different types of sockets (i.e., designed to mate with different types of plugs) and may be configured to allow chaining of PDUs (i.e., connecting one PDU to another PDU). As noted above, a PDU can be designed to distribute one, two or three phases of power into a cabinet. It is also common for two PDUs to be deployed into a single cabinet to provide redundant power feeds to the equipment deployed into the cabinet. The redundant power feeds may be the same or different phases and may come from different UPSs or even a utility power higher in the distribution chain.

The PDU circuitry is fixed and, for the purposes of the examples described herein, will be referred to as the X, Y, and Z phases. N is used to denote neutral. Certain PDUS, such as PDU 20(1), will utilize one of the phases and neutral as the two references provided at each socket. Other PDUs, such as PDU 20(3), will utilize two of the three phases, and these same two phases will be provided as references at each socket. Still other PDUs, such as PDU 20(2) or PDU 20(4), will utilize all three phases and potentially the neutral circuit. As shown in FIG. 1, three phase PDU 20(2) has three groups of sockets, with each group consuming from the same two reference circuits.

In the example of FIG. 1, the facility phase and neutral circuits are wired or mapped to the PDU phase and neutral circuits at power whips 24(1)-24(4). That is, in this example, it is at the bottom or lowest-level component in the power distribution chain where a choice can be made as to which phases of power will be fed into a specific location or cabinet in the data center.

A DCIM system, such as DCIM system 10, is a device, such as a server, computer, mobile device, etc., that is configured to run a DCIM application as described herein. As noted above, DCIM system 10 comprises a user interface unit 40, processor 45, and a memory 50 that includes DCIM application 55. DCIM system 10 may be located at data center 5, or may be a remote device with access to the facility via a local area network (LAN), a wide area network (WAN), etc. It is to be appreciated that the DCIM system 10 and hosting of DCIM application 55 are merely provided for illustration purposes, and may not reflect how the infrastructure management techniques may be implemented in practice. For example, other implementations will span multiple platforms (e.g., the client platform talking to a web server platform which talks to a database server platform), use virtual machines, etc.

Memory 50 of DCIM system 10 may comprise read only memory (ROM), random access memory (RAM), magnetic disk storage media devices, optical storage media devices, flash memory devices, electrical, optical, or other physical/tangible memory storage devices. The processor 45 is, for example, a microprocessor or microcontroller that executes instructions for the DCIM application 55. Thus, in general, the memory 50 may comprise one or more tangible computer readable storage media (e.g., a memory device) encoded with software comprising computer executable instructions and when the software is executed (by the processor 45) it is operable to perform the operations described herein in connection with DCIM application 55.

As noted, in the example of FIG. 1, DCIM application 55 is stored in, and executed from, memory 50. It is to be appreciated that, in alternative examples, the DCIM application may be hosted external to DCIM system. For example, the DCIM application may be hosted on a server, or may be a web-based application that is accessed through system 10.

For ease of illustration, DCIM application 55 will be described herein by referring to specific operations that are performed by the DCIM application. As would be appreciated, DCIM application 55 does not, in practice, perform such operations, but rather such actions are performed by a processor, controller or other component that executes the instructions of DCIM application 55. As such, reference to operations performed by DCIM application 55 should be interpreted as operations implemented through the execution of DCIM application instructions by one or more other components.

Generally, DCIM application 55 is configured to monitor, at certain components in the system, characteristics representing the consumption of power across a plurality of power phases. DCIM application 55 is configured to analyze the monitored characteristics to determine the consumption of power, at a phase-level (i.e., at each of the phases of power that is utilized in the power distribution system), for each of the plurality of monitored components. The DCIM application 55 is configured to use the locally obtained power consumption characteristics (i.e., from one or more components), to determine the power consumption (projected, actual, maximum) for all other components in the power distribution chain. DCIM application 55 is configured to determine, at the local components, a global representation of the power consumption at a phase-level for one or more of the plurality of components in the chain. The above operations allow the configuring of one or more pieces of equipment in the data center 5 (or planned pieces of equipment) so that a resulting deployment balances the consumption over the three phases L₁, L₂, and L₃.

DCIM application 55 may be configured to monitor various components in power distribution chain 38, including sub-panel 15, whips 24(1)-24(4)), or the PDUs 20(1)-20(4). As noted above, the components in the power distribution chain, or elements of components, are associated with one or more circuit breakers or fuses. For example, the breakers are associated at the phase-levels within the component. As noted above, these breakers have specific ratings and capabilities and, as such, it is at these locations that the components may fail. Accordingly, the monitoring may occur at these breakers or at other locations that provide an indication of the capacity of a component (with reference to capacity remaining or an indication of the current usage). The monitored characteristics may include amperage, power, etc. with reference to the utilized phase. As noted above, these characteristics may be obtained in real-time, for use in determining actual, maximum, or projected power consumption at the phase-level.

As noted above, the DCIM application 55 enables a determination of how the various power phases in a data center are used, and enables the determination and configuration of the data center layout so that the data center is configured to consume power across the available power phases in a balanced fashion. One step in enabling this determination is to represent the power distribution chain in the application on user interface unit 40. In one example, a forest of expandable trees can be used to represent the power distribution chain, and allow a user to open a parent component in the power chain and view its children. At each component of the power distribution chain, the DCIM application 55 may determine and display the maximum (M), projected (P), and actual (A) consumption of power in kilowatts (kW) and amperage (Amps). The following text depicts the M, P and A values for power in kW of power distribution chain 1, noted above.

### Power Distribution Chain 1

### Component A (M: 2500 kW, P: 1000 kW, A: 800 kW)

### Component B-1 (M: 500 kW, P: 200 kW, A: 150 kW)

### Component C-1 (M: 144 kW, P: 0 kW, A: 150 kW)

### Component C-2 (M: 144 kW, P: 0 kW, A: 0 kW)

### Component B-2 (M: 500 kW, P: 300 kW, A: 200 kW)

### Component C-3 (M: 144 kW, P: 0 kW, A: 0 kW)

### Component C-4 (M: 144 kW, P: 300 kW, A: 200 kW)

In addition to introducing the M, P, and A values at the component, the DCIM application 55 is configured to determine these values at each phase within the component. For example, at Component C-4 in Power Distribution Chain 1, above, these values are as follows:

### Component C-4 (M: 144 kW, P: 300 kW, A: 200 kW)

### Phase A (M: 48 kW, P: 150 kW, A: 100 kW)

### Phase B (M: 48 kW, P: 150 kW, A: 100 kW)

### Phase C (M: 48 kW, P: 0 kW, A: 0 kW)

After the DCIM application 55 provides the power distribution chain, the application is further configured to map the facility phases to the PDU phases. As noted above, the facility phases are being represented as L₁, L₂, and L₃, and N for neutral. Following are the possible combinations of the facility phases: L₁L₂, L₁L₃, L₂L₃, L₁N, L₂N, and L₃N. Also as noted above, the PDU phases are represented as X, Y, Z and N for neutral, with possible reference combinations of XY, XZ, YZ, XN, YN, and ZN. In general, the PDU wiring is fixed and the wiring inside the distribution panel is fixed. The mapping occurs when connecting wires between distribution panels or between a distribution panel and the PDU. When using the PDU phase nomenclature, the same socket will have the same two references. It is to be appreciated that, in certain circumstances, this mapping occurs at every point in the distribution chain and not only at the PDUs.

Different facility to PDU mappings will cause different facility phases to be provided at the same socket. The DCIM application 55 provides a means to map the facility references to the PDU references, and to reconfigure as desired. More generally, DCIM application 55 provides the ability to perform this mapping between any two components, not only at a PDU and a distribution panel.

With the PDUs wired to the facility power distribution chain, and the IT equipment plugged into PDU sockets, the IT equipment's projected consumption can be determined at specific facility references or phases. Accessing the PDUs through the network, the DCIM application 55 can then gain access to the actual consumption characteristics of the power being drawn at each phase.

Furthermore, DCIM application 55 is configured to provide the projected and actual power characteristics at a cabinet and phase-level by totaling up the phase consumption at all sockets in a PDU (e.g., sockets 21(1)-21(12) of PDU 20(1)) and all PDUs in a cabinet. Furthermore, the projected and actual power consumption characteristics at a higher level component can be obtained by totaling up the phase consumption at all children devices wired into that higher level component. Totaling all of the child component's phase consumption of a parent component in a power distribution chain provides power consumption characteristics of the parent component. The ability to calculate the power consumption from the PDUs, at the phase-level, up through the power distribution chain, provides the information used to determine which sockets should be selected to balance power consumption when plugging a device into a PDU.

In one example described further below, the DCIM application 55 is configured to guide a user by displaying and highlighting sockets with globally underutilized phase consumption and that have a configuration that can mechanically mate with the plug of a specific piece of equipment. As detailed below, within the DCIM application 55, this is accomplished by clicking on a representation of a piece of equipment and virtually plugging it into the optimal socket.

As noted above, DCIM application 55 is configured to monitor and obtain characteristics that represent the consumption of power at the phase-level at one or more components in the power distribution chain. In certain circumstances, the consumption is time stamped to provide analytics used to identify patterns of consumption over time. Examples may include identifying when systems are being heavily used (e.g., maybe because of “black Friday”) or lightly used (e.g., in the two hours associated with a shift change) or other unexpected peaks and lulls that might provide insight into making the overall data center more efficient. As such, DCIM application 55 is configured to determine that a specific group of equipment (e.g., servers) becomes heavily utilized at the same time, thereby causing their associated support equipment (e.g., network components and storage components) to become more active. In this case, the opportunity exists to configure this group of servers to consume from different phases within the facility's power distribution system. This allows for a more balanced consumption of power across the phases, and better utilization of the facility's power distribution system.

The DCIM application 55 is configured to use built-in monitors that can be deployed at various points within the power distribution chain 38. These monitors may not use actual monitors to be present at a location where a built-in monitor is deployed. That is, even if there is no real measurement, by propagating values through the distribution chain, as noted above, DCIM application 55 is configured to infer what the measurement would have been (at a specific location), and use this to monitor consumption and/or generate alarms/warnings. The monitors provide real-time feedback at the component and phase-levels, and tie the two together. Inherent behavior in the built-in monitors allows them to be associated with actual monitors at the same time, and at different areas of the distribution chain, to identify and isolate undesirable behavior within the power distribution system.

The built-in monitors are created and defined when the user creates a power chain component. When creating a power chain component, there are a number of attributes that are defined for the component to function. Of particular interest to the built-in monitors are the voltage amplitude provided, the amperage rating of the component, and the derating factor of the component. The user will enter the supplied voltage, component amperage rating, and the desired derating factor as a percentage. As an example:

Supplied Voltage=480 volts

### Component Amerage Rating=3248 Amps

### Derating Factor=1

The Maximum Power for this 3-Phase component is calculated for the user by using Equation 1, provided below.

Max Power=(Supplied Voltage*Amperage Rating*Derating Factor)/1000*SQRT(3) Equation 1:

Note, dividing by 1,000 provides the results in kW. If this division was not used, the units would be watts.

The calculated Max Power warning and alarm threshold are defined as a percentage of the Max Power for the component, and max amperage for the phases. If a warning and or alarm threshold is crossed, the DCIM solution notifies the user by one or more of color changes in the facility power distribution chain or the virtual space power distribution chain, entries into a message center and event log, programmatically generated emails, pages to the assigned administrators, etc. The planned and actual units of values compared against the aforementioned thresholds are then virtually determined by executing the a PDU update event, an update of a childless power chain component, and an update of a parent power chain component process described elsewhere herein.

Through the use of monitors, the DCIM application 55 can identify peaks, averages, and valleys in units of consumption within a window of time, and map them back to business events. For example, it may be desirable to implement changes in a data center's infrastructure when less activity is occurring so as to limit the potential impact of the change. To help reduce risk, the changes could be scheduled to coincide with the valleys in the power consumption.

As noted, peaks/valleys in consumption can be correlated to business events and allow projections into the future to ensure the events will not exceed the available resources. As an example, if the quarterly and annual results for a company can be correlated with their peak consumption of power, and one or more events can be mapped to their peak consumption, then the data can be used to ensure the events could occur simultaneously or to determine if it is desirable to execute the events in a serial fashion.

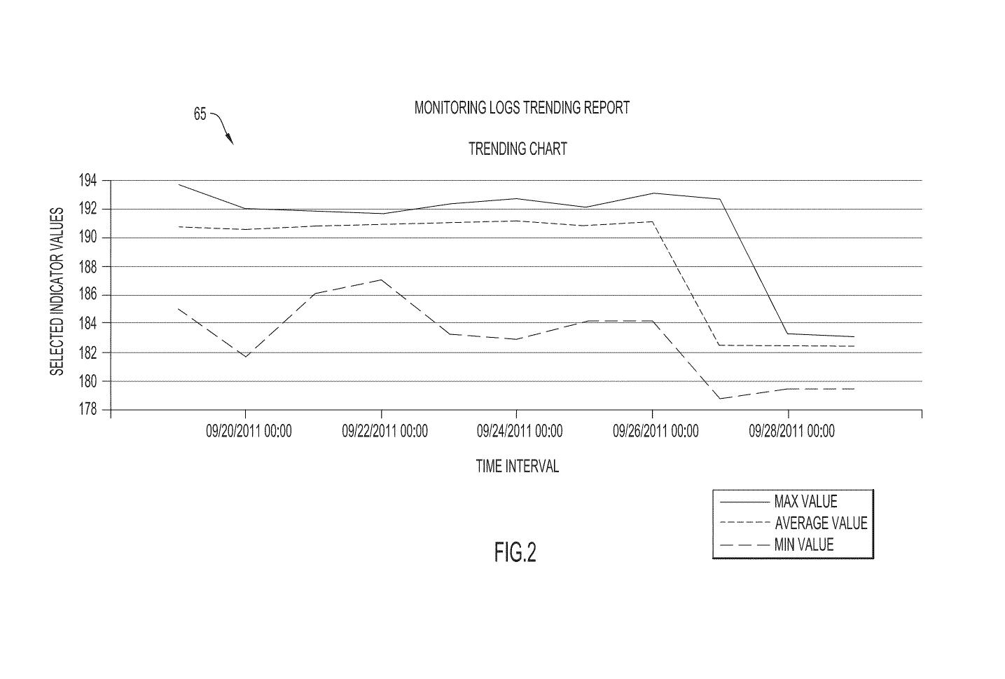

To realize the aforementioned analytics, the high, average, and low units of consumption within a window of time are determined. However, the resolution of how these are collected is also considered. Collection resolutions allow the peak, average, and valley units of consumption to be mapped to different entities, including: devices (pieces of equipment), cabinets, rows, halls, data centers, or clients. The solution to apply the analytics allows the user to identify the peak, average, and low power consumption at the aforementioned resolution (device, cabinet, row, hall, data center, or client). FIG. 2 is a chart 65 illustrating the graphing of analytics over time, namely power being captured at a Hall resolution over time.

Additionally, the analytics may be used to map average units of consumption back to a client consuming the resource (e.g., average kW consumed at a specific window of time, client consumption billing) or to compare projected kW against actual kW for implemented devices. If it is determined that a device has exceeded a predetermined deviation (i.e., a percentage deviation), a message could be sent to the administrators indicating that there is an issue at the identified location in the data center (i.e., expected consumption is not matching actual consumption).

Data collected from the PDU(s) can be used to project actual and planned consumption across the phases at any component level within the power distribution system. With these rollups it is possible to identify consumption issues at any component in the distribution chain and monitor various threshold crossings at the components and at the different phases within the components.

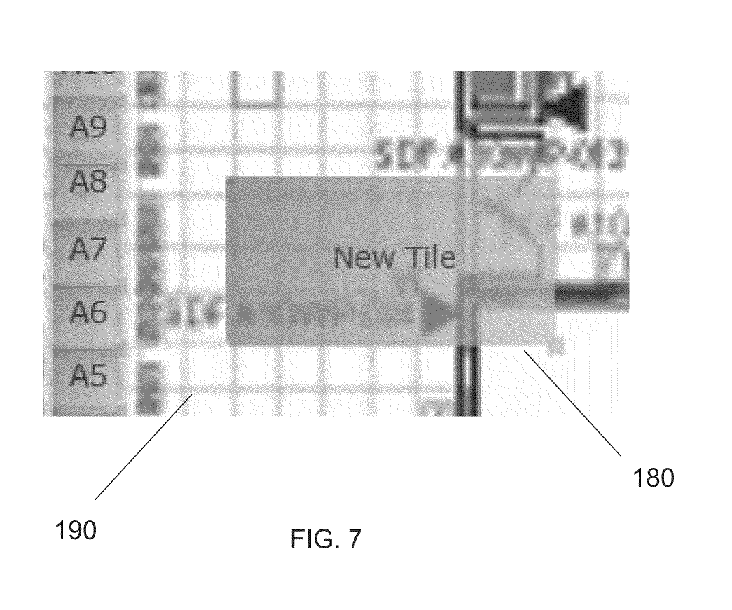

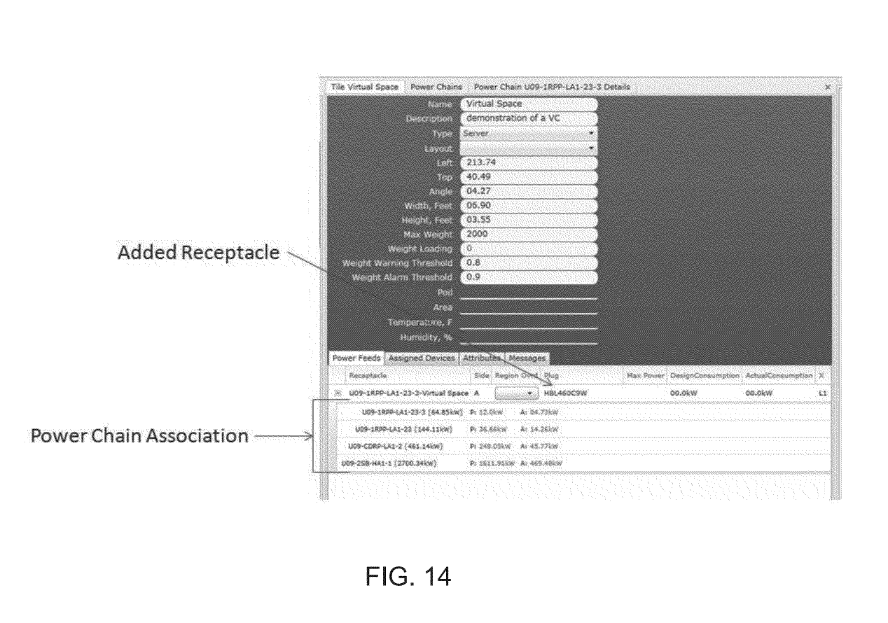

As described below, DCIM application 55 is configured to provide one or more management interfaces (via user interface unit 40) that may be operated by a user to manage different voltage amplitudes used for different equipment deployments. Further details of these management interfaces are provided below with reference to FIGS. 7-32.

The DCIM application 55 provides one or more of the following advantages and capabilities. In certain circumstances, DCIM application 55 ensures that power consumption of a data center remains balanced across all utilized distribution phases. This capability is available to data center administrators, facility administrators, or other users during the planning, implementation and operations stages of a data center's lifecycle. For example, in one implementation, the infrastructure management application determines how specific devices (to be deployed), having specific power consumption characteristics, should be plugged into a data center's power distribution chain, down to the socket (outlet) that should be used.

Additionally, the DCIM application 55 may take into account historic, current, and projected (planned) phase consumption to provide new ways to intelligently deploy equipment into the power distribution system. Utilization of the DCIM application 55 may substantially eliminate the use of remediation by deploying equipment in a manner that balances consumption at the phase-level. The DCIM application 55 guides a data center planner or other user to plug device power cords into sockets with the least utilized power phases. By consuming power across the phases in a balanced fashion, the DCIM application 55 ensures that all resource capacities at a facility are consumed to their upmost potential, thereby substantially eliminating stranded power, space, and port connectivity within the facility. In addition to highlighting the optimal socket to balance consumption across the phases, the DCIM application 55 may also highlight feasible mechanical mates between power cords and power sockets.

In one specific example of FIG. 1A, five pieces of equipment, such as computers, servers, networking devices (e.g., switches, routers, firewalls, load balancers), storage systems, environment controls (e.g., air conditioning, fire suppression), security devices, etc.), are plugged into PDUs 20(1)-20(4). More specifically, a first piece of equipment (not shown in FIG. 1A) that draws approximately 1.5 kilowatts (kWs) is plugged into socket 21(1), a second piece of equipment (not shown in FIG. 1A) that draws approximately 3.5 kWs is plugged into socket 21(6), a third piece of equipment (not shown in FIG. 1A) that draws approximately 1.5 kWs is plugged into socket 22(1), a fourth piece of equipment (not shown in FIG. 1A) that draws approximately 10 kWs is plugged into socket 22(12), and a fifth piece of equipment (not shown in FIG. 1A) that draws approximately 10 kWs is plugged into socket 23(5).

In this example, the first and second pieces of equipment draw power from phase L₁, the third piece of equipment draws power from phases L₁ & L₂, the fourth piece of equipment draws power from phases L₂ & L₃, and the fifth piece of equipment draws power from phases L₂ & L₃. Table 1, below, illustrates the total power consumed for each of the first through fifth pieces of equipment, and the power consumed on each of the phases L₁, L₂, and L₃.

TABLE 1

| | Total Power | | | |
|---|---|---|---|---|
| Equipment | Consumed | Phase L₁ | Phase L₂ | Phase L₃ |
| First | 1.5 kW | 1.5 kW | 0 kW | 0 kW |
| Second | 3.5 kW | 3.5 kW | 0 kW | 0 kW |
| Third | 1.5 kW | .75 kW | .75 kW | 0 kW |
| | | (i.e. 1.5 kW/2) | (i.e. 1.5 kW/2) | |
| Fourth | 10 kW | 0 kW | 5 kW | 5 kW |
| | | | (i.e. 10 kW/2) | (i.e. 10 kW/2) |
| Fifth | 10 kW | 0 kW | 5 kW | 5 kW |
| | | | (i.e. 10 kW/2) | (i.e. 10 kW/2) |

Table 2, below, illustrates the total power consumed by each PDU 21(1)-21(3) (i.e., the PDUs that have attached equipment), and the resulting power consumed on each of the phases L₁, L₂, and L₃.

TABLE 2

| | Total Power | | | |
|---|---|---|---|---|
| PDU | Consumed | Phase L₁ | Phase L₂ | Phase L₃ |
| 20(1) | 5 kW | 5 kW | 0 kW | 0 kW |
| 20(2) | 11.5 kW | .75 kW | 5.75 kW | 5 kW |
| | | (i.e. 1.5 kW/2) | (i.e. 1.5 kW/2 + | (i.e. 10 kW/2) |
| | | | 10 kW/2) | |
| 20(3) | 10 kW | 0 kW | 5 kW | 5 kW |
| | | | (i.e. 10 kW/2) | (i.e. 10 kW/2) |

As such, Table 3, below, illustrates the total power consumed, and the power consumed for each phase L₁, L₂, and L₃ in data center 5.

TABLE 3

| Total Power | | | |
|---|---|---|---|
| Consumed | Phase L₁ | Phase L₂ | Phase L₃ |
| 26.5 kW | 5.75 kW | 10.75 kW | 10 kW |

As is clear from the above example, nearly twice the power is consumed via each of PDUs 20(2) and 20(3) as is consumed via PDU 20(1). Similarly, nearly twice the power is consumed on each of phases L₂ and L₃ as is consumed on phase L₁. A DCIM application as described herein is configured to balance the three-phase power consumption at the planning, implementation, and operations stages of a data center's lifecycle.

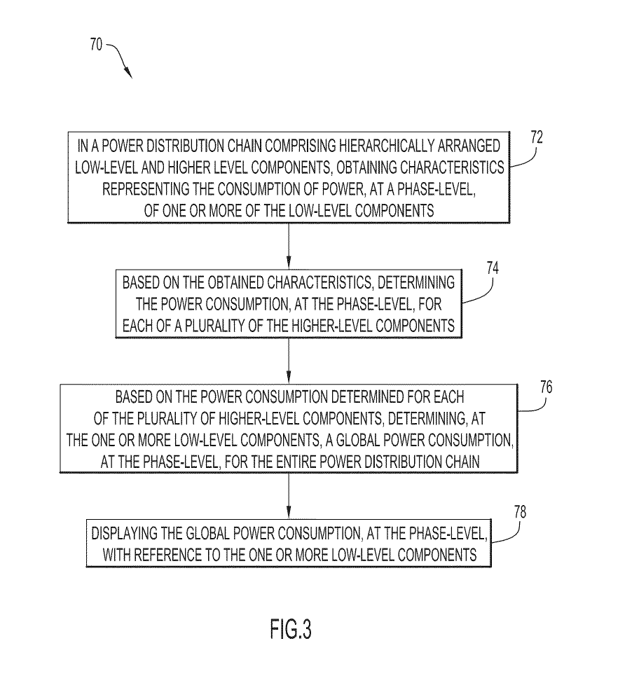

FIG. 3 is a flowchart of one example method 70 for managing the power distribution chain of a data center comprising a plurality of hierarchically arranged low-level and higher-level components. Method 70 begins at 72 with obtaining characteristics representing the consumption of power, at a phase-level, of one or more low-level components in the power distribution chain. At 74, based on the obtained characteristics, the method further includes determining the power consumption, at the phase-level, for a plurality of higher-level components in the power distribution chain. At 76, the method comprises, based on the power consumption determined for each of the plurality of higher-level components, determining, at the one or more low-level components, a global power consumption, at the phase-level, for the entire power distribution chain. At 78, the method includes displaying the global power consumption, at the phase-level, with reference to the one or more low-level components.

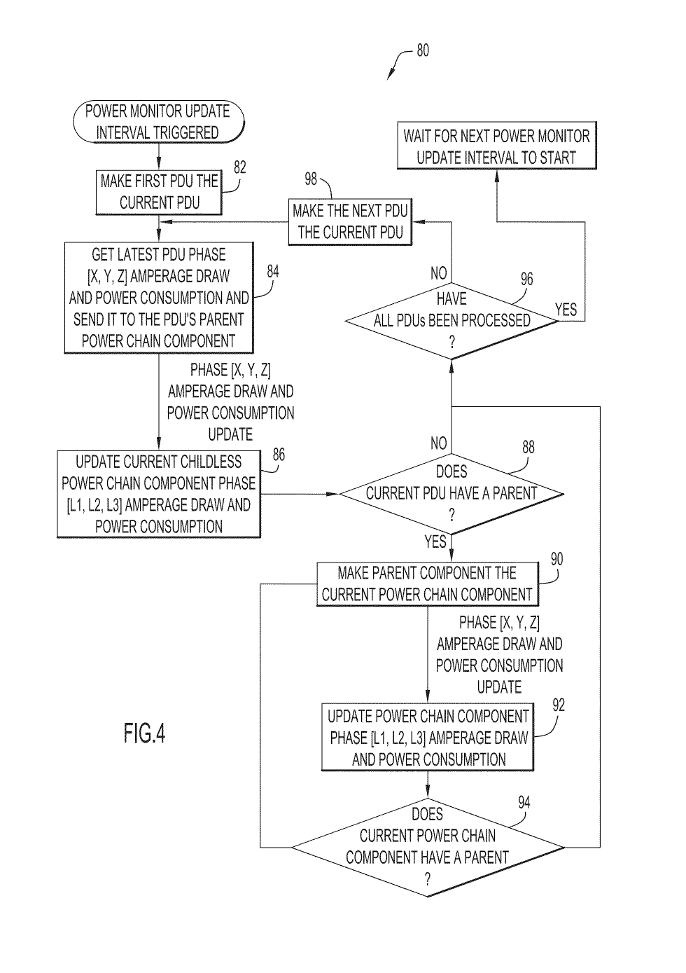

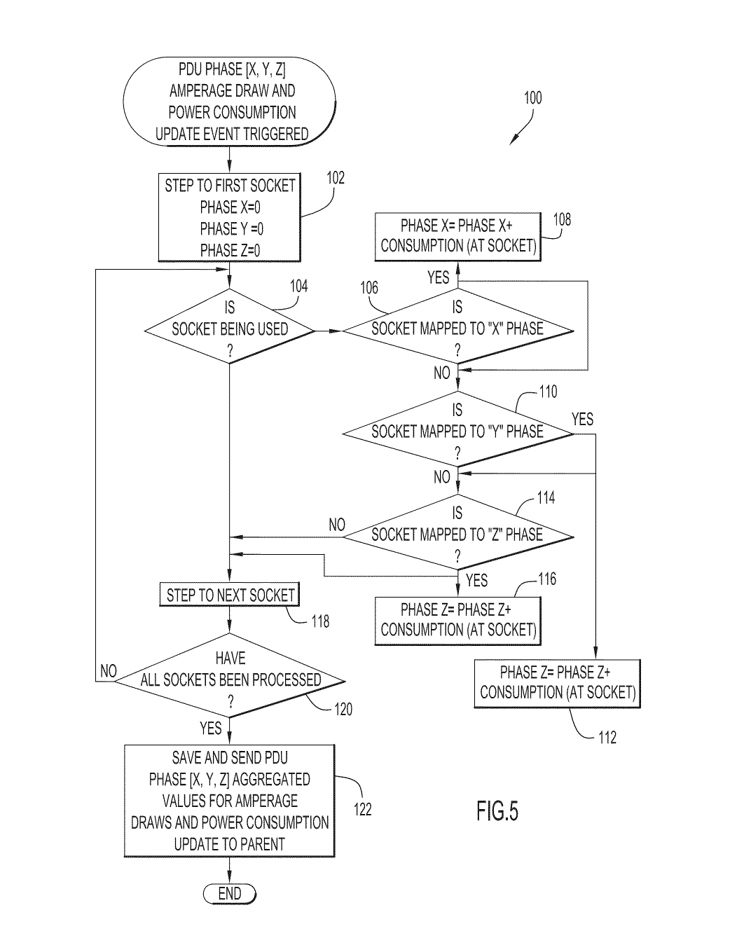

FIG. 4 is a flowchart of a method 80 implemented during determining the global power consumption of components in a power distribution chain. The operations of FIG. 4 occur at a time referred to as the power monitor update interval. These power monitor updates may occur at predetermined or customized times.

At 82, a first PDU is made the current PDU. At 84, the latest PDU phase (X, Y, Z) amperage draw and power consumption for the current PDU is obtained and sent to the current PDU's parent power chain component. At 86, the childless power chain component phase (L₁, L₂, and L₃) amperage draw and power consumption is updated. At 88, a determination is made as whether the current PDU has a parent. If not, method 80 proceeds to 96, described below. If the current power chain component does have a parent, method 80 proceeds to 90 where the parent component in the power chain is made the current power chain component. At 92, the power chain component phase amperage draw and power consumption is updated. At 94 a determination is made as to whether the current component has any parent components. If so, steps 90, 92, and 94 are repeated until the top of the power chain is reached. If not, method proceeds to 96.

At 96, a determination is made if all PDUs have been processed. If so, method 80 ends and waits for the next power monitor update interval. If all PDUs have not been processed, method 80 proceeds to 98 where the next PDU is made the current PDU. The above steps are repeated until the power consumption for all PDUs and higher-level components has been determined.

FIG. 5 is a method 100 for performing a PDU phase [X, Y, Z] amperage draw and power consumption update. Method 100 starts at 102 where the updated values for the first socket phases (X, Y, and Z) are set to zero. At 104, a determination is made if the socket is being used. If the socket is being used, method 100 proceeds to 106 where a determination is made as to whether the socket is mapped to phase X. If so, at 108, the phase X values for the socket are updated to include the consumption at the socket.

If, at 106, the socket is not mapped to the X phase, or if the operations at 108 are completed, the method proceeds to 110 where a determination is made as to whether the socket is mapped to phase Y. If so, at 112, the phase Y values for the socket are updated to include the consumption at the socket.

If, at 110, the socket is not mapped to the Y phase, or if the operations at 112 are completed, the method proceeds to 114 where a determination is made as to whether the socket is mapped to phase Z. If so, at 116, the phase Z values for the socket are updated to include the consumption at the socket.

Returning to 104, if the socket is not being used, the method proceeds to 118. Similarly, if at 114 the socket is not mapped to the Z phase, or after the completion of the operations at 116, method 100 proceeds to 118. At 118, the method steps to the next socket. At 120, a determination is made as to whether all sockets have been processed. If not, the method returns to 104. If all sockets have been processed, the method proceeds to 122 where the X, Y, and Z values (amperage draw and power consumption) are aggregated and sent as an update to the parent.

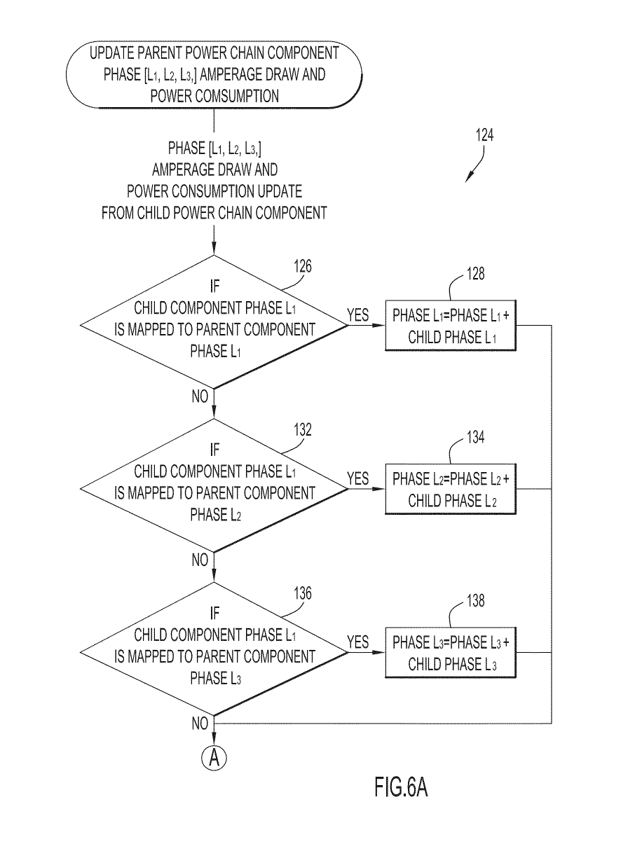

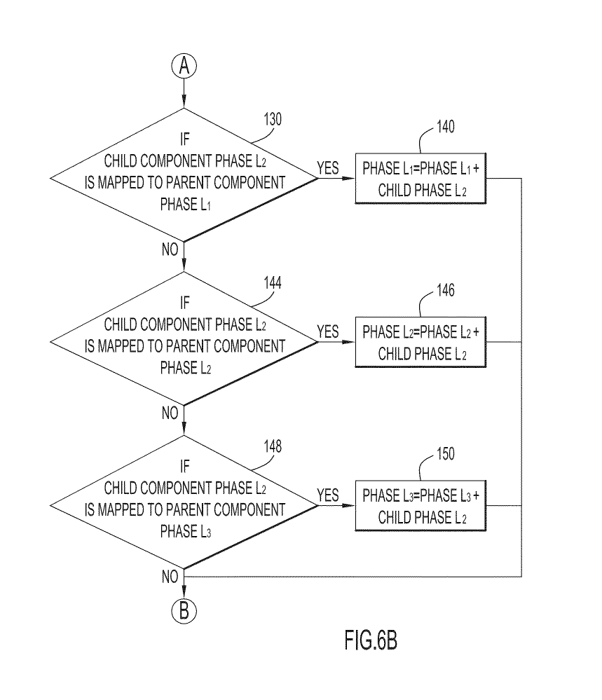

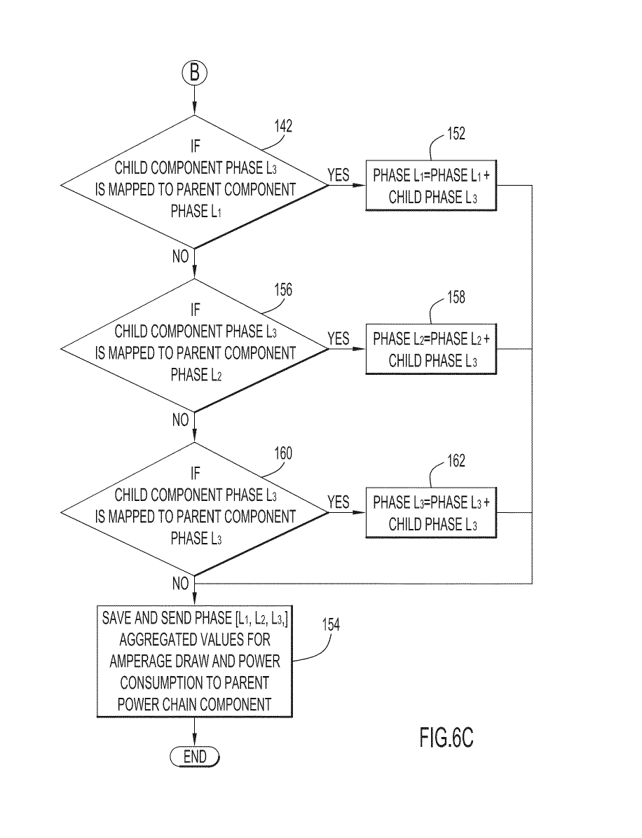

FIGS. 6A-6B collectively illustrate a flowchart of a method 124 in which the power component chain phase (L₁, L₂, and L₃) amperage draw and power consumption are updated. At 126, a determination is made as to whether the child component phase L₁ is mapped to parent component phase L₁. If so, the method proceeds to 128 where the values for L₁ are updated (i.e., Phase L₁=PhaseL₁+Child PhaseL₁). After 128, the method proceeds to 130, described further below.

If the child component phase L₁ is not mapped to parent component phase L₁, the method proceeds to 132. At 132, a determination is made as to whether the child component phase L₁ is mapped to parent component phase L₂. If so, the method proceeds to 134 where the values for L₂ are updated (i.e., Phase L₂=PhaseL₂+Child PhaseL₂). After 128, the method proceeds to 130.

If the child component phase L₁ is not mapped to parent component phase L₂, the method proceeds to 136. At 136, a determination is made as to whether the child component phase L₁ is mapped to parent component phase L₃. If so, the method proceeds to 138 where the values for L₃ are updated (i.e., Phase L₃=PhaseL3+Child PhaseL₃). After 128, the method proceeds to 130.

At 130, a determination is made as to whether the child component phase L₂ is mapped to parent component phase L₁. If so, the method proceeds to 140 where the values for L₁ are updated (i.e., Phase L₁=PhaseL₁+Child PhaseL₂). After 140, the method proceeds to 142, described further below.

If the child component phase L₂ is not mapped to parent component phase L₁, the method proceeds to 144. At 144, a determination is made as to whether the child component phase L₂ is mapped to parent component phase L₂. If so, the method proceeds to 146 where the values for L₂ are updated (i.e., Phase L₂=PhaseL₂+Child PhaseL₂). After 146, the method proceeds to 142.

If the child component phase L₂ is not mapped to parent component phase L₂, the method proceeds to 148. At 148, a determination is made as to whether the child component phase L₂ is mapped to parent component phase L₃. If so, the method proceeds to 150 where the values for L₃ are updated (i.e., Phase L₃=PhaseL3+Child PhaseL₂). After 150, the method proceeds to 142.

At 142, a determination is made as to whether the child component phase L₃ is mapped to parent component phase L₁. If so, the method proceeds to 152 where the values for L₁ are updated (i.e., Phase L₁=PhaseL₁+Child PhaseL₃). After 152, the method proceeds to 154, described further below.

If the child component phase L₃ is not mapped to parent component phase L₁, the method proceeds to 156. At 156, a determination is made as to whether the child component phase L₃ is mapped to parent component phase L₂. If so, the method proceeds to 158 where the values for L₂ are updated (i.e., Phase L₂=PhaseL₂+Child PhaseL3). After 158, the method proceeds to 154.

If the child component phase L₃ is not mapped to parent component phase L₂, the method proceeds to 160. At 160, a determination is made as to whether the child component phase L₃ is mapped to parent component phase L₃. If so, the method proceeds to 162 where the values for L₃ are updated (i.e., Phase L₃=PhaseL3+Child PhaseL3). After 162, the method proceeds to 142.

At 162, the L₁, L₂, and L₃ values are aggregated and sent to the next parent component in the power chain. The method then ends.

As noted above, a DCIM application is used to implement infrastructure management and three-phase power balancing techniques described herein. FIGS. 7-18 and 20-32 are screenshots of a user interface unit displaying windows generated by a processor executing a DCIM application, such as DCIM application 55, described above. In the example of FIGS. 7-32, a planned deployment is illustrated.

The example DCIM application 55 allows a user to create a “virtual space” in a data center of interest (i.e., a data center being managed through the use of the application). A virtual space is a location of interest in the data center at which power may be made available for use by pieces of equipment. Each virtual space can have zero or more diverse feeds of power which allow for redundant power sources that ensure continued operation of the equipment in the event of a power feed failure. FIG. 7 is a screenshot showing a virtual space (semi-transparent tile) 180 overlaying a representation of a data center 190 generated by DCIM application 55. As would be appreciated, a software application, such as DCIM application 55, may employ any number of different techniques (e.g., menu, pull down display, different modes, etc.) that allow a user to create the virtual space 180. The illustrative examples described herein should not be construed as limited to any specific techniques for providing the various illustrated features.

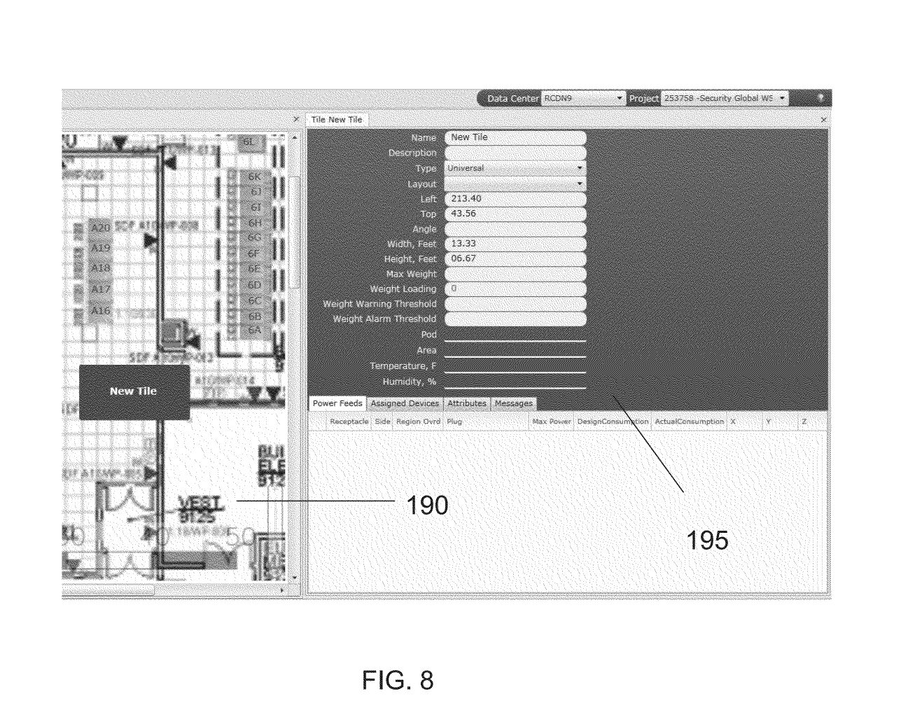

The size, shape, arrangement, etc. of virtual space 180 is not limited and may take a number of different combinations. In one example, the virtual space 180 can be configured by double clicking on the virtual space. Double clicking on the virtual space 180 will highlight the virtual space and bring up a dialog 195 that is shown in the screenshot of FIG. 8. The dialog 195 can be used, for example, to configure and view many different characteristics or states for the location in the data center that was selected for virtual space 180. At this point, the virtual space 180 may be further configured by changing its attributes, including its name, adding a description, resizing the space, reorienting the space, defining weight constraints, etc. Dialog 195 is shown in FIG. 8 next to the data center representation 190.

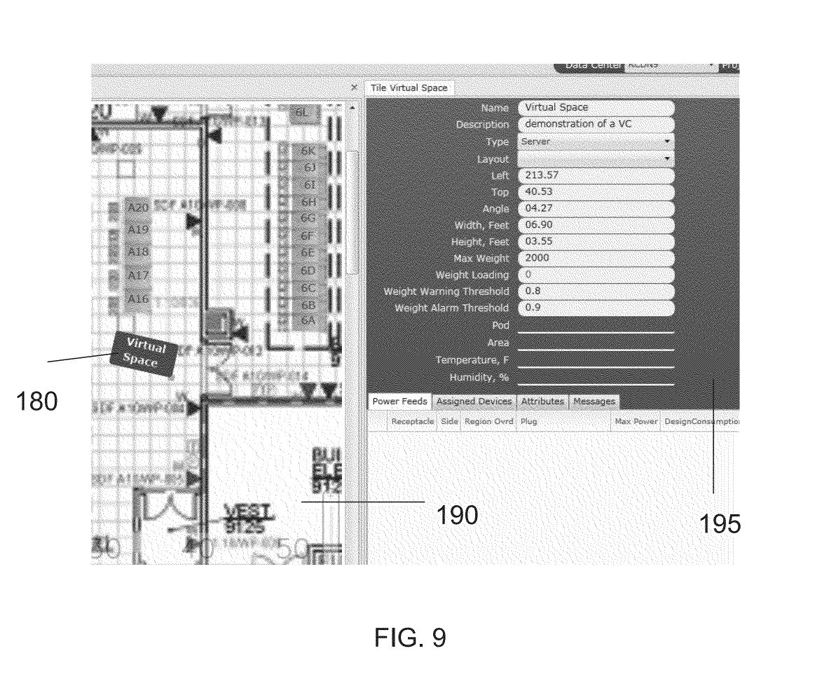

After changes to the attributes of virtual space 180, dialog 195 may appear as shown in FIG. 9. Additionally, virtual space 180 is modified to reflect the changed attributes. For example, in FIG. 9, virtual space 180 is shown at an angle (4.27 degrees), width (6.90 feet), height (3.55 feet), etc., as set in dialog 195.

As noted above, power is distributed from the utility feeds entering the data center all the way down to the individual devices (equipment) such as the servers, storage, network switches and routers, etc., in the data center. As the power is distributed to virtual space 180, it may be transformed to appropriate voltage amplitudes, and the desired phases are selected. Each device feeding from the supplied power uses at least two reference points from the phases of power and may use neutral circuits that can be provided to the virtual space 180. Within DCIM application 55, the power distribution chain can be created, edited or viewed. This may be, for example, by selecting a “Power Chain” option item from a “Floor Plan” menu, or through the use of other techniques as known in the art.

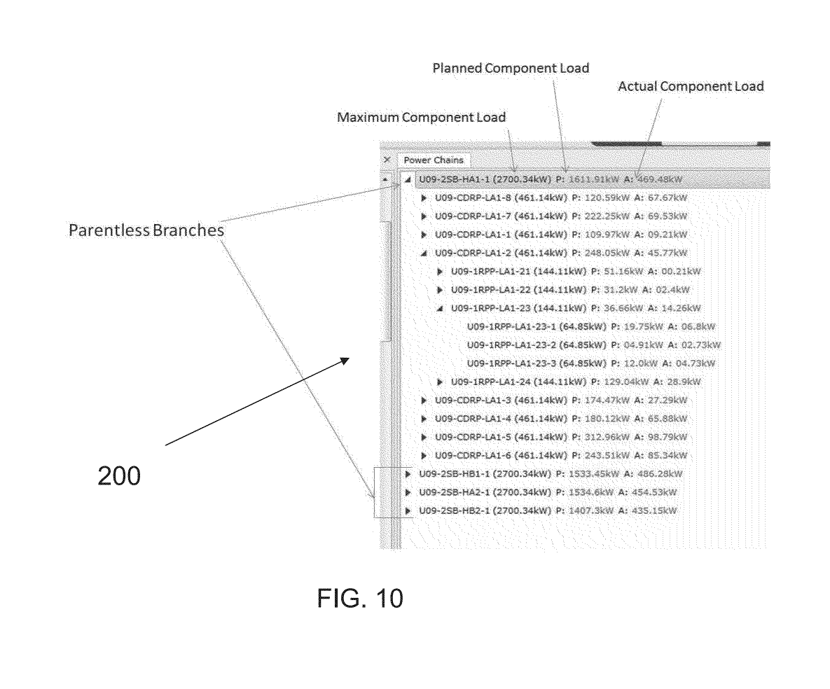

Data centers generally each have unique power distribution chains. As such, DCIM application 55 is configured to provide the ability to create, edit, and view each of these different data center chains. In one example, this is accomplished via an expandable tree view that uses the parent and child branches to identify the different components in the power distribution chain, as well as the associations between the branches. FIG. 10 is a screenshot illustrating an example representation of a power distribution chain 200.

Power distribution chain 200 illustrated in FIG. 10 has four parentless components which, in this case, are UPS components that have a maximum load capability of 2.7 MW or 2700 kW. The initial UPS (the UPS named “U09-25B-HA1-1”) has been expanded to show the immediate child components that feed from this UPS. DCIM application 55 provides flexible naming conventions for all power distribution components, thus allowing naming convention(s) used by the designers of the facility to be honored.

In the example of FIG. 10, there are eight immediate child components (containing the “CDRP” characters), each rated for a maximum load of 461 kW that feed from the UPS “U09-25B-HA1-1.” If each of these components consumed power at or near its maximum load rating, the parent component would have well exceeded its maximum load rating. Building out the power distribution chain in this way ensures power can be supplied in a flexible fashion. However, there is the potential for child components, working in concert, to surpass the capabilities of a parent component. As such, it is useful to manage the consumption of the children, from a planned and actual perspective, to ensure the parent components are not overwhelmed. As noted above, this ability is enabled by DCIM application 55. Oversubscription of this type is important to avoid stranding power and overbuilding infrastructure components.

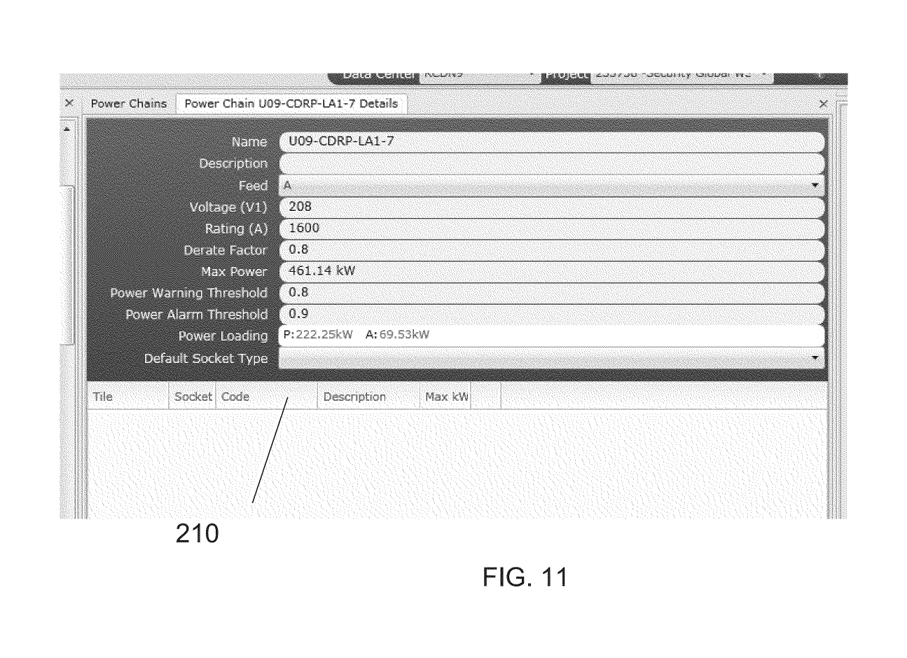

FIG. 11 is a screenshot of a dialog 210 that enables the characteristics of each component in the power distribution chain to be defined. In one example, dialog 210 can be reached by double clicking on the desired component in the power chain of FIG. 10. In the illustrative example of FIG. 11, the characteristics of the components include name, description, feed, voltage (line), rating (amps), derating Factor (% of Rating, Max Power (calculated from the aforementioned entries), warning and alarm thresholds (% of the calculated max power), etc. Voltage amplitude transformations can occur between the parent and child components in the distribution chain by altering the “Voltage (V1)” value in the components detail dialog in the different components.

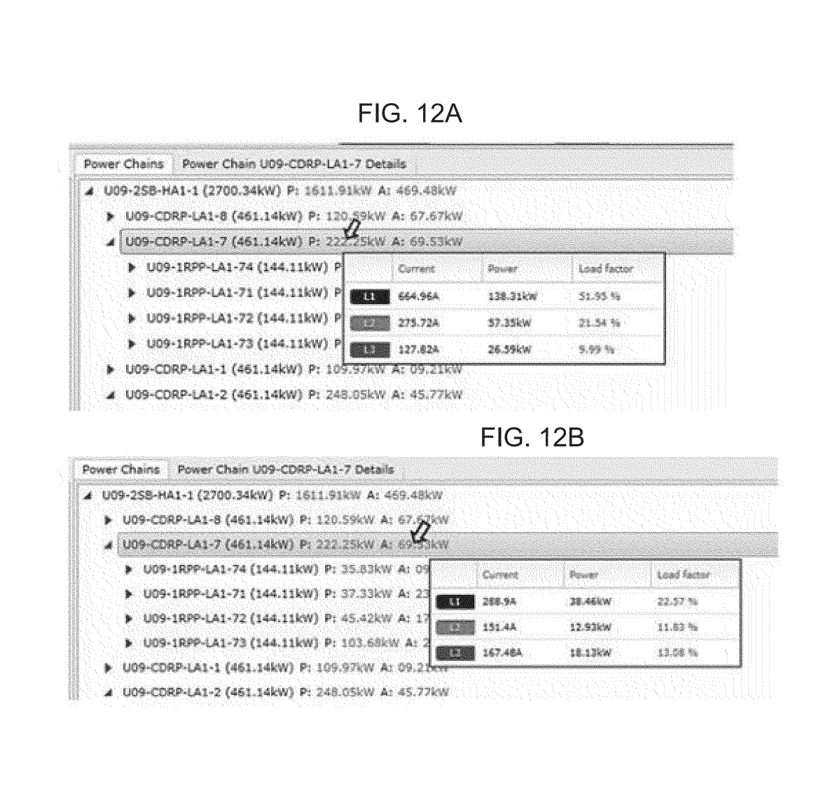

With the power distribution chain in place, an initial view of managing power at the phase-level can be shown. In one example of FIGS. 12A and 12B, when the user's cursor is placed over either the projected (planned) or actual power numbers at a component in the power distribution chain, a view of the consumption across the phase circuits is provided to the user. FIG. 12A illustrates example values when the cursor is placed over the planned power, while FIG. 12B illustrates example values when the cursor is placed over the actual power.

It is at each of the phases L₁, L₂, and L₃ at which a breaker is defined and, if exceeded, there is the potential for the entire component to fail. The DCIM application 55 provides the current draw, power consumption, and load with respect to a phase. As the current draw approaches the component's amperage draw ratings on a particular phase, DCIM application 55 will go first into a “warning state” and a warning message may be displayed to a user. If the draw continues to increase, DCIM application 55 may enter an “alarm state” and an alarm (visual or audible) may be provided. The warning and alarm levels are tied back to how the component was configured in the dialog of FIG. 11.

With the virtual space 180 and the representation of power distribution chain 200 in place, DCIM application 55 can now provide power to the virtual space 180 from one or more childless components in the power distribution chain. Power is provided to virtual space 180 by highlighting the spaces of interest, and then assigning them to a childless component in the power distribution chain using one or more software tools, such as a drop down menu. After the virtual space 180 is associated with the component in the power distribution chain, the details of the virtual space can be revisited.

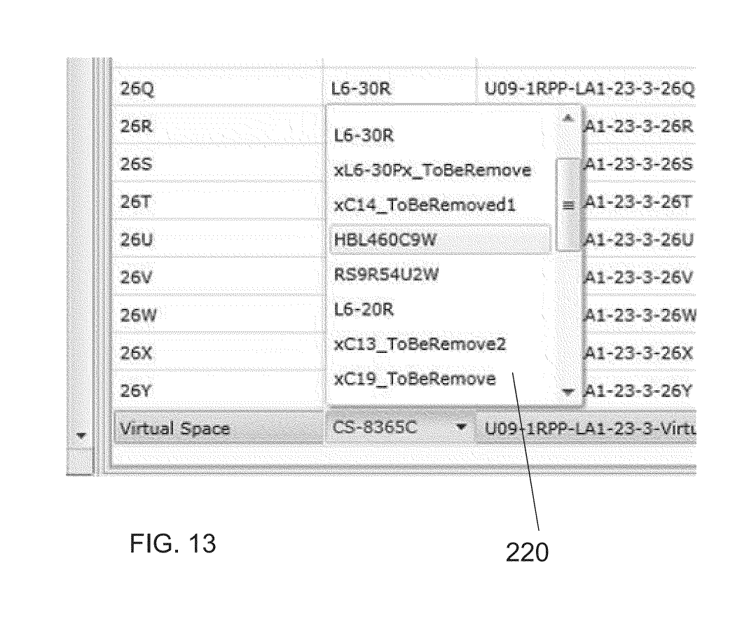

From the perspective of the component in the power distribution chain, a power whip or receptacle has been created to provide power at the virtual space 180. In this example, the default socket in this case is a type of socket labeled “CS-8365C.” As shown in the screenshot of FIG. 13, the socket type can be easily changed by opening a drop down list 220 of sockets and selecting the desired socket. In FIG. 13, the socket is changed from a “CS-8365C” to a “HBL460C9W.” These receptacles are nothing more than a type of socket which will mate with one or more specific plugs. DCIM application 55 manages these mechanical connections to ensure alignment between the sockets and plugs occurs.

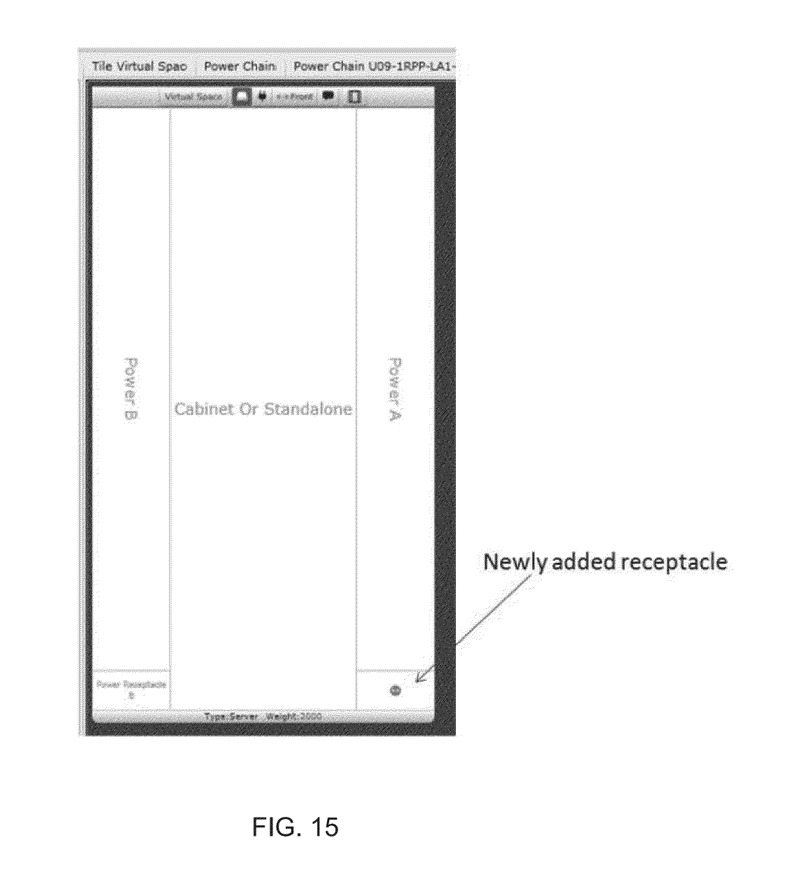

A look at the addition of the receptacle from the perspective of the virtual space 180 is possible by re-accessing the virtual space detail view. FIG. 15 is a screenshot illustrating an elevation view of virtual space 180. As shown, a single power feed (new receptacle) has been added to the virtual space 180.

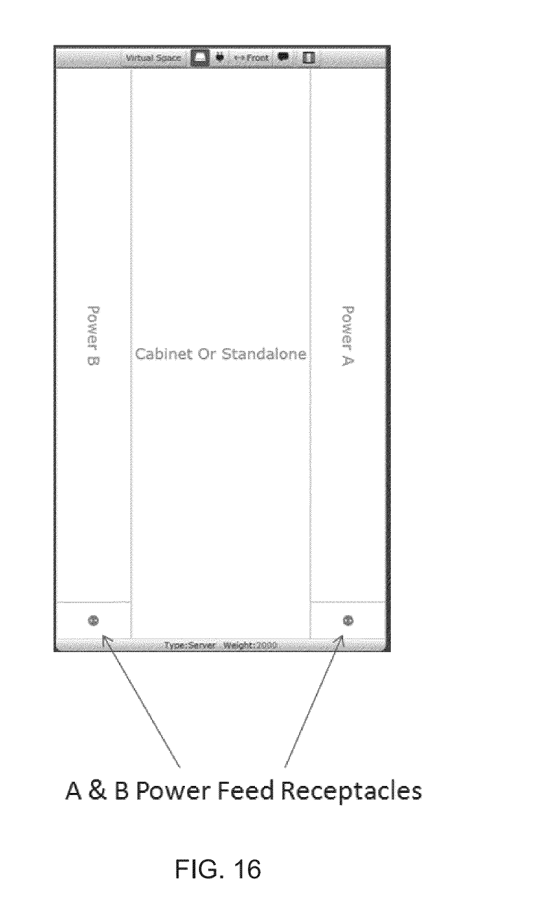

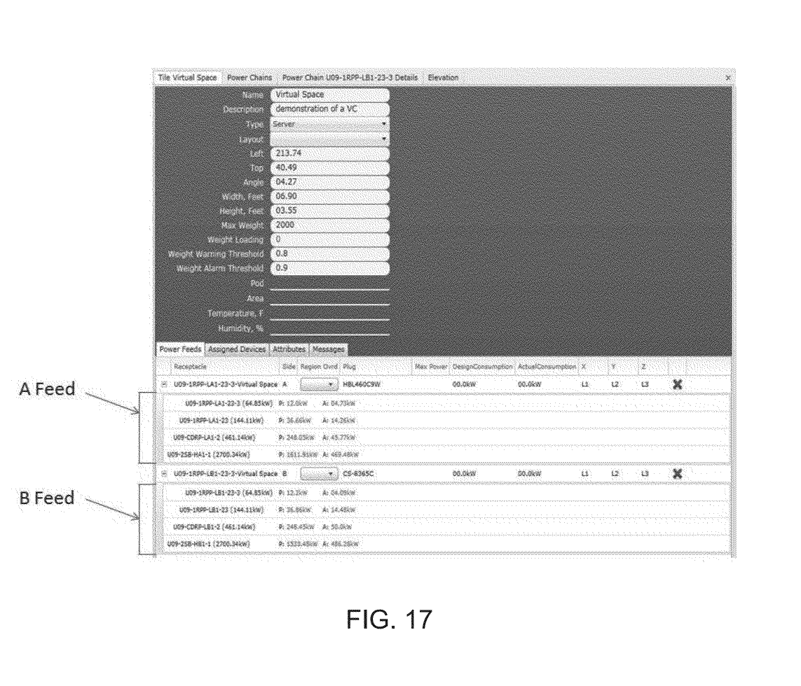

A second feed may also be added to provide redundant power feeds to virtual space 180. This may occur in substantially the same manner as described above, including associating the virtual space 180 with the same of a different childless component. A second, different childless component in the power distribution chain could be used, for example, to provide power redundancy. After association of the virtual space 180 with a second feed, the elevation has a second receptacle providing power to the virtual space, as shown in FIG. 16. Furthermore, after the association of the virtual space 180 with the second feed, the virtual space details dialog, shown in FIG. 17, now shows two power distribution feeds at the virtual space. As is evident to one skilled in the art, any number of feeds could be associated with a given virtual space and the ideas presented here would be valid.

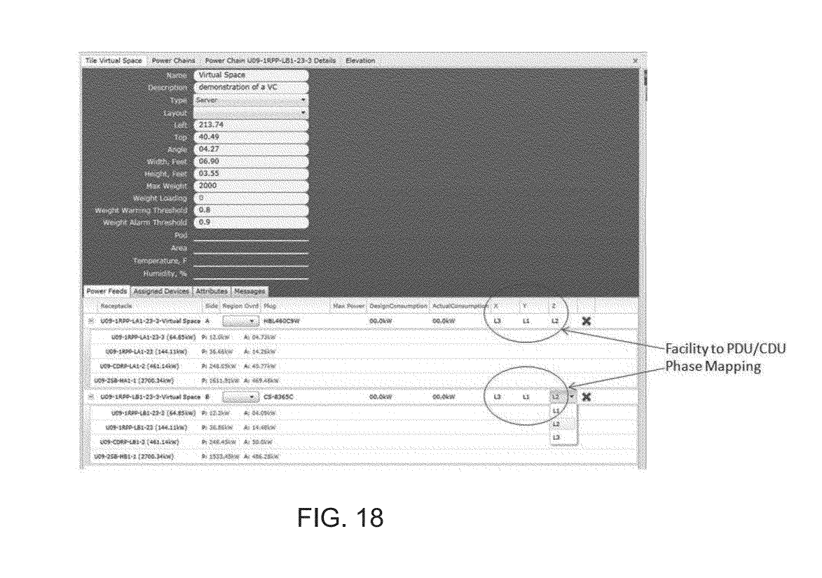

As previously noted, DCIM application 55 is configured to map a desired facility phase to a desired PDU phase, or to map phases between distribution panels. The facility feeds are identified as L₁, L₂, and L₃ and the PDU phases identified by the X, Y, and Z. The current example maps L₁ to X, L₂ to Y, and L₃ to Z. In certain circumstances, the facility phase to PDU phase mappings can be altered. For example, L₃ may be mapped to X, L₁ to Y and L₂ to Z. FIG. 18 is a screenshot of a dialog 225 that allows altering of these mappings.

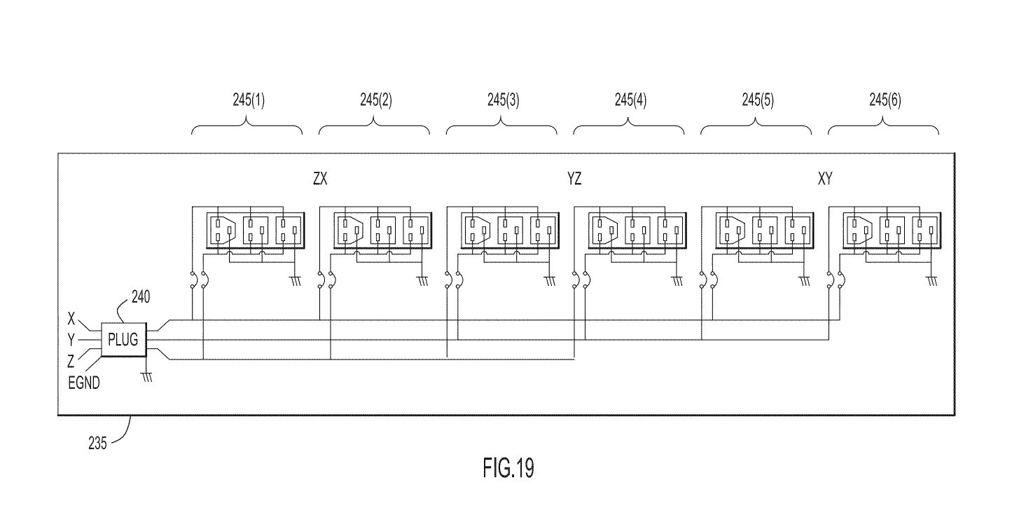

Once the facility phases are mapped to the PDU phases, the PDU construction determines which phases are presented at which sockets for consumption. FIG. 19 is a schematic diagram illustrating the internal circuitry for a specific PDU 235. As shown, the X, Y, and Z phase circuits enter the PDU through plug 240, then the six banks 245(1)-245(6), each comprising three sockets, tie into two of the three supplied phases. The first six sockets (i.e., the sockets in banks 245(1) and 245(2)) tie into the Z and X phases, the next six sockets (i.e., the sockets in banks 245(3) and 245(4)) tie into the Y and Z phases, and the remaining six sockets (i.e., the sockets in banks 245(5) and 245(6)) tie into the X and Y phases.

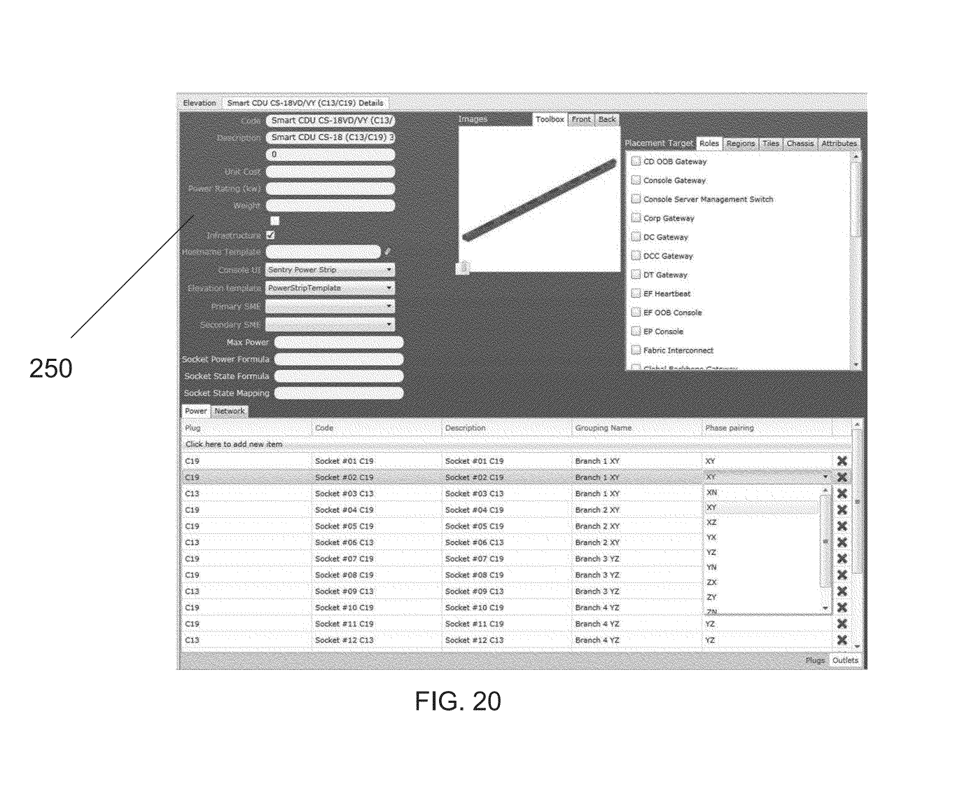

Using the facility to PDU mapping of DCIM application 55, the facility phases provided at the first six sockets (i.e., the sockets in banks 245(1) and 245(2)) would be the L₃ and L₂ phases, the facility phases provided at the next six sockets (i.e., the sockets in banks 245(3) and 245(4)) would be the L₁ and L₂ phases, and the facility phases provided at the next six sockets (i.e., the sockets in banks 245(5) and 245(6)) would be the L₃ and L₁ phases. DCIM application 55 manages phase consumption using the facility's notation, and uses the PDU notation to map the facility phases up to the sockets in which equipment plugs are inserted into the sockets. FIG. 20 is a screenshot of a dialog 250 illustrating how a socket (socket #02) can be mapped to a number of phase pair references by opening a dropdown list.

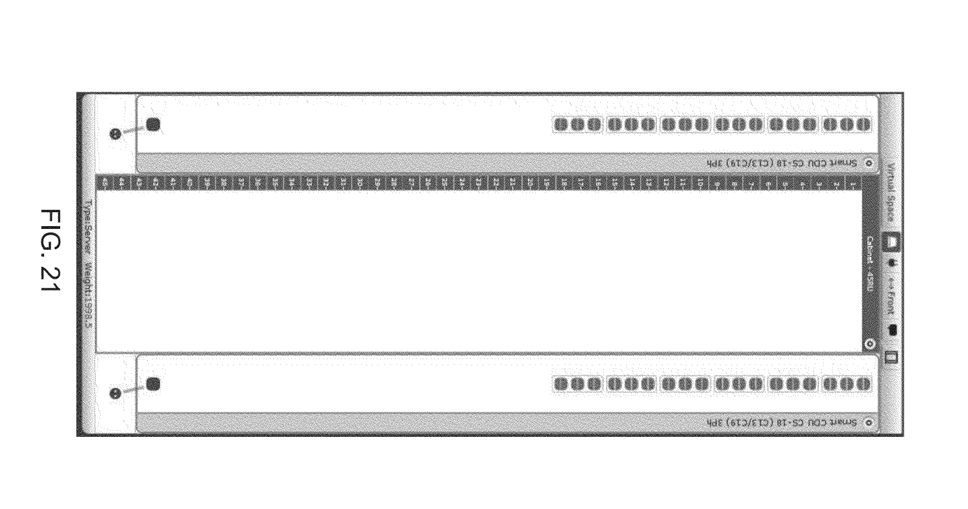

In order to patch a device's power cord into the PDU and consume power at the phases, a cabinet is placed on the virtual space, the PDU is placed in the virtual space's power regions, and the PDU power cord is plugged into the virtual space's receptacles. FIG. 21 is a screenshot showing virtual space 180 after the cabinet has been deployed, the L₁ and L₂ power feed PDUs have been deployed, and their power cords have been plugged into the virtual space's power receptacles.

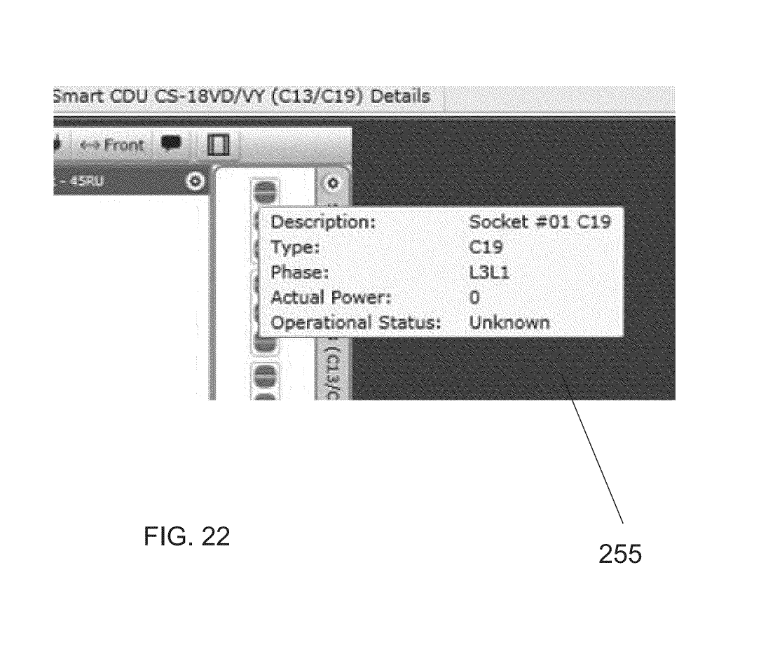

After the PDUs are deployed and their power cords are patched into the facility receptacles, the sockets on the PDU provide phase consumption feedback by coloring the sockets to indicate the phase consumption (e.g., green, yellow and red to reflect phase consumption). In one example, a socket has two halves with two different colors that each reflect the two phase references provided at the socket. As shown in FIG. 22, placing the cursor over the socket causes a dialog 255 to appear that identifies the phases supplied at the socket.

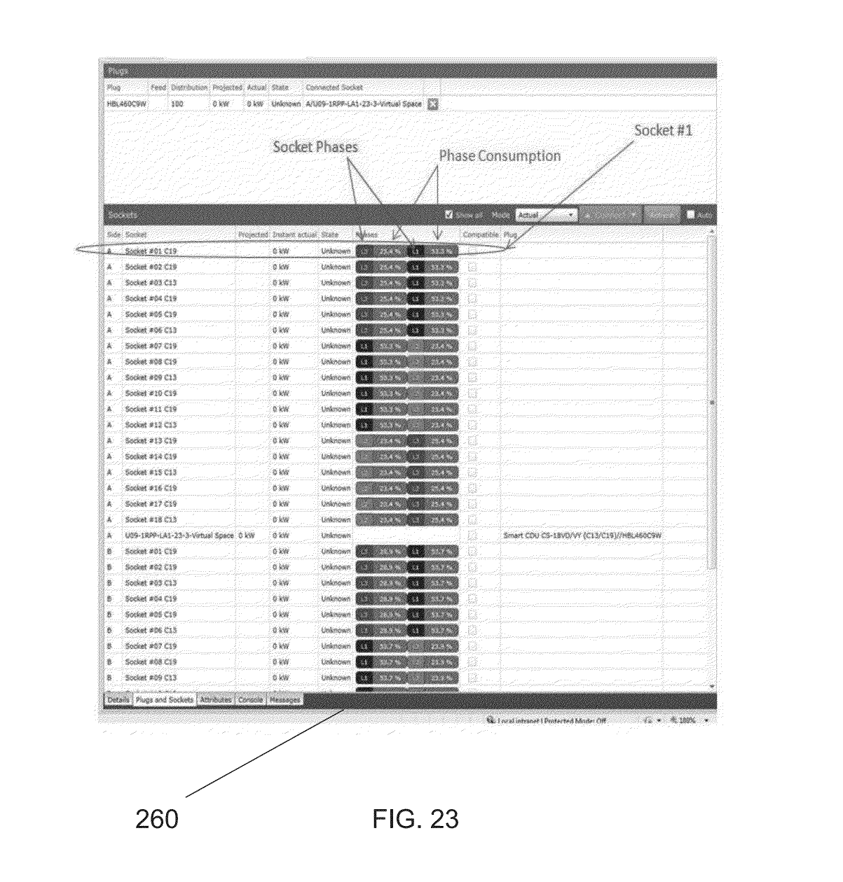

A different view is provided by opening up a device's detail view associated with the virtual space and selecting a “Plugs and Sockets” view that brings up a dialog 260 (shown in FIG. 23). In this example, the PDU is the device having its details shown.

The “Plugs and Sockets” dialog 260 has a tabular view of the sockets provided at the virtual space and identifies the phases mapped to the socket. In addition to identifying phases, the worst case phase consumption thru the entire power distribution chain is provided. In FIG. 23, the column that identifies the phases and the worst case consumption of that phase thru the entire power distribution chain is unique and provides visibility to deploy devices in the data center, while at the same time allowing for the balancing of phase consumption to ensure optimal performance with respect to ROI.

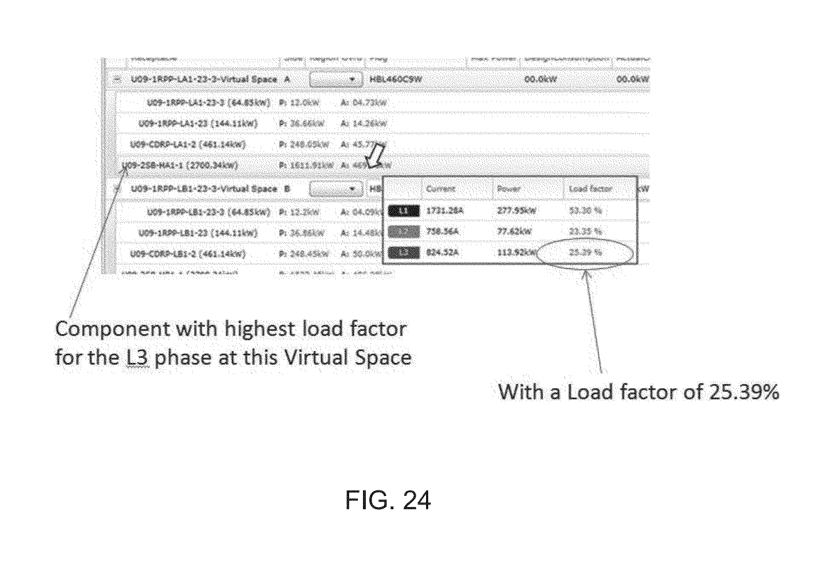

FIG. 23 is a screenshot showing the representation of the power distribution chain, as noted above. This example illustrates the loading at each component in the power distribution chain used to provide power at virtual space 180, at the phase-level, and is expressed as a percentage. The loading percentage may not be the load at the cabinet, but rather it can identify any component participating in this virtual space's power distribution chain. As seen in FIG. 23, the L₃ phase is loaded at 25.4% at one of the four components of the power distribution chain. In this example, the component is the UPS. By placing the cursor over the actual values, the load factor for the L₃ phase is presented at 25.39%, as shown in FIG. 24.

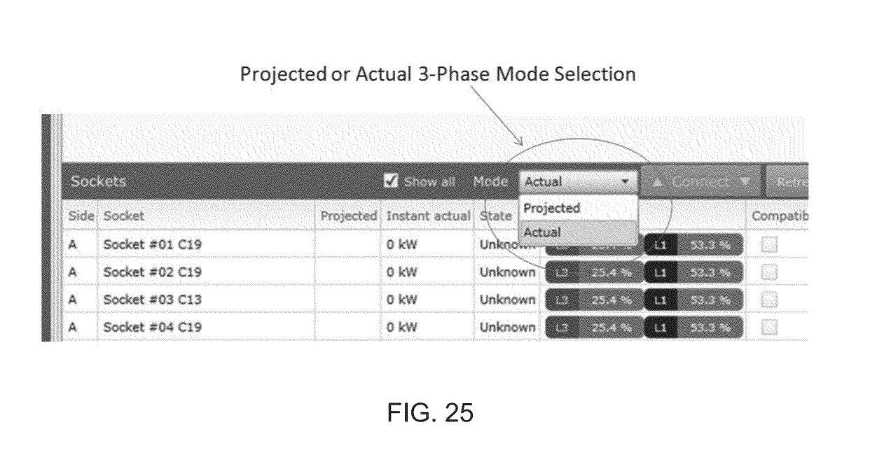

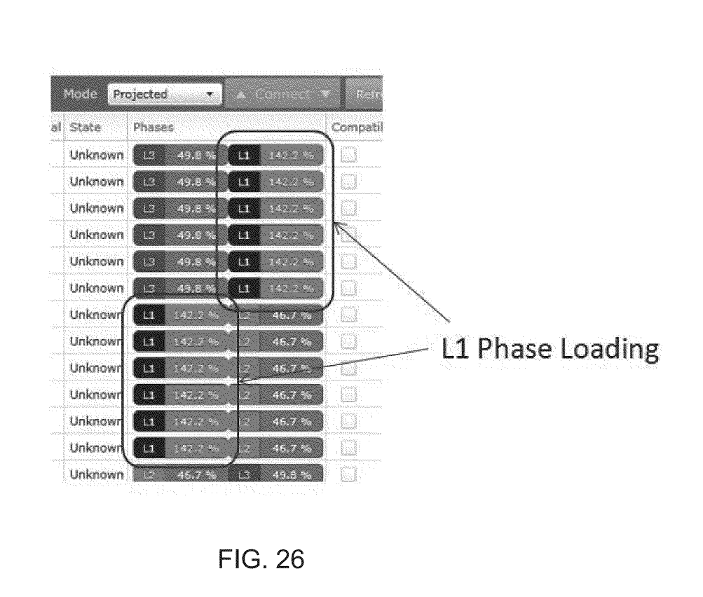

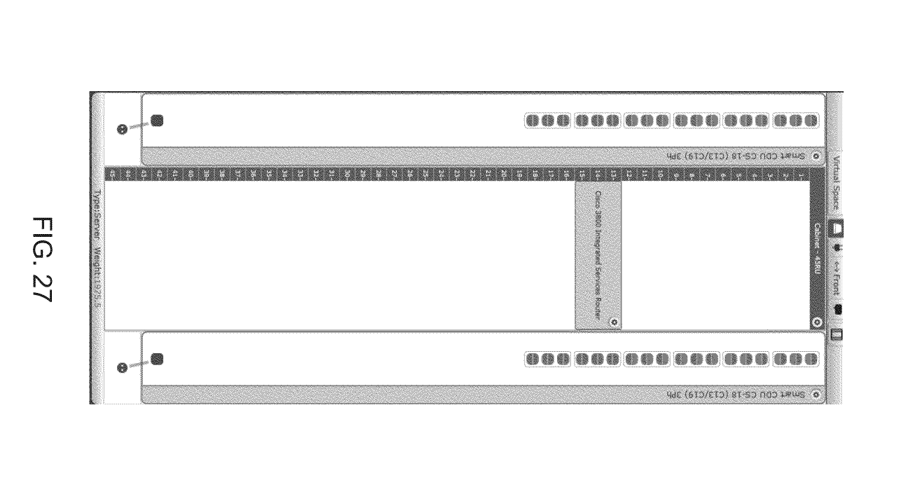

As noted elsewhere herein, the DCIM application 55 provides visibility to the virtual space's entire power distribution chain at a phase-level resolution (when planning new equipment deployments and when operating). As shown in FIG. 25, within the “Plugs and Sockets” view, DCIM application 55 provides the ability to select a view of either the projected or the actual three-phase power characteristics of virtual space 180. Changing from the actual to the projected mode alters the consumption and status views at the virtual space's elevation and the “Plugs and Sockets” view of any device deployed at the virtual space. These changes are shown in FIG. 26 and FIG. 27.

With the “projected” mode selected, the L₁ phase loading has jumped up to 142.2% and has transitioned from being colored green to red. In this case, the planned deployments are exceeding at least one of this virtual space's power chain component's maximum phase capacities by 42 percent. In a similar fashion the elevation view would now reflect the overloaded L₁ phase at the sockets in which L₁ is provided, as shown in FIG. 27.

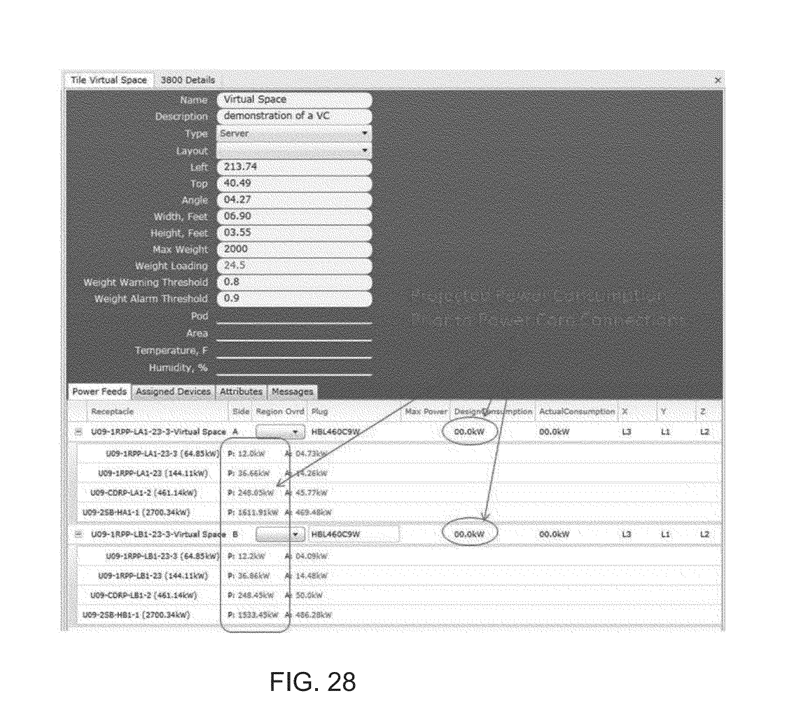

In FIG. 27, an integrated services router (IRS) is deployed in the cabinet in virtual space 180. In this example, the IRS is positioned at rack unit number 13. By clicking on the plug icon on the top of the cabinet, the elevation enters a new mode referred to as the power mode. While in the power mode the power cord connections from the IRS to the sockets in a PDU can be created. Prior to making these connections, the projected power across the power distribution components will be captured as shown in FIG. 28.

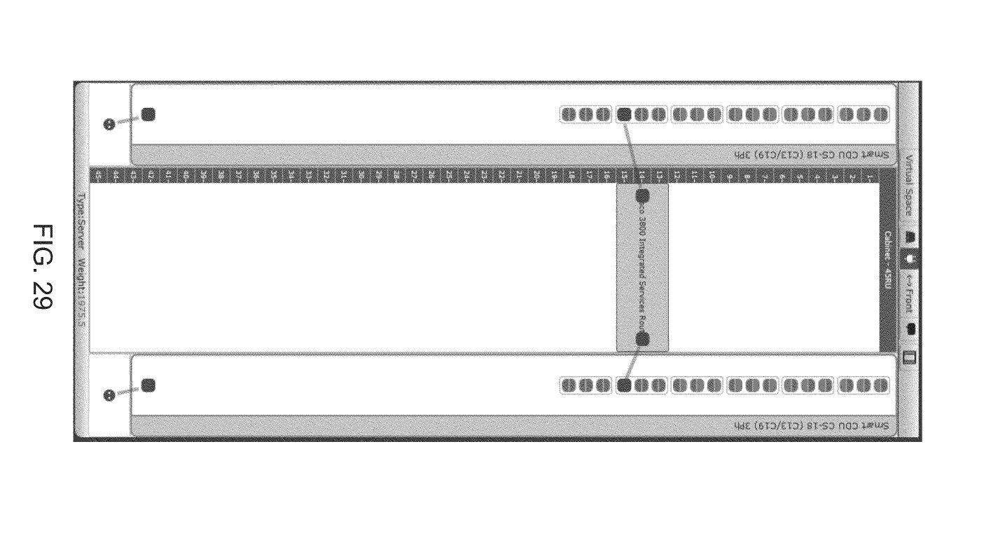

After connecting the power cords, the virtual space elevation would appear as shown in FIG. 29. As shown, the power cords connections have avoided the L₁ phases by plugging into the sockets with underutilized phase consumption.

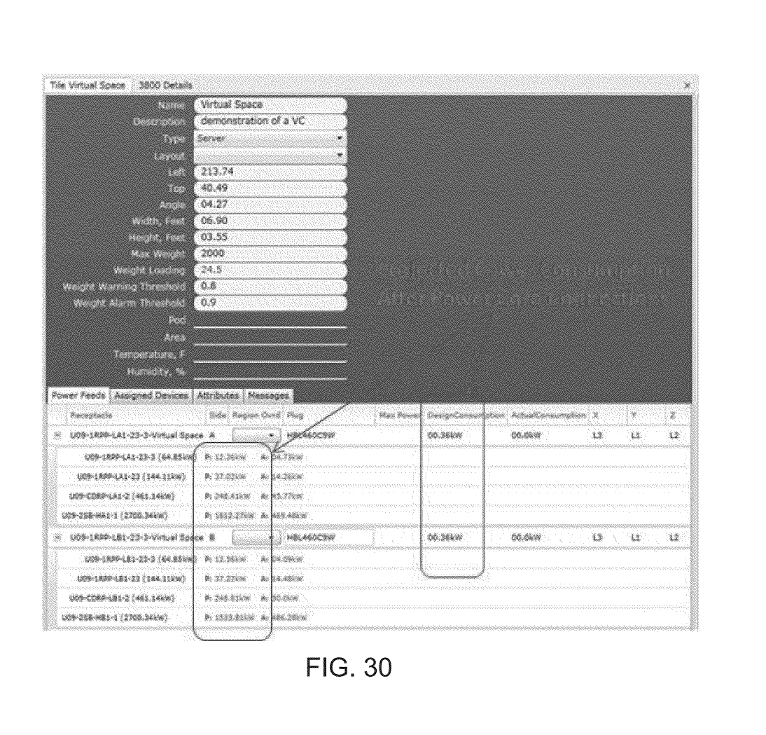

With the power cord connections in place, the virtual space details dialog, shown in FIG. 30, now shows the projected consumption of 360 watts on the L₁ and L₂ phases.

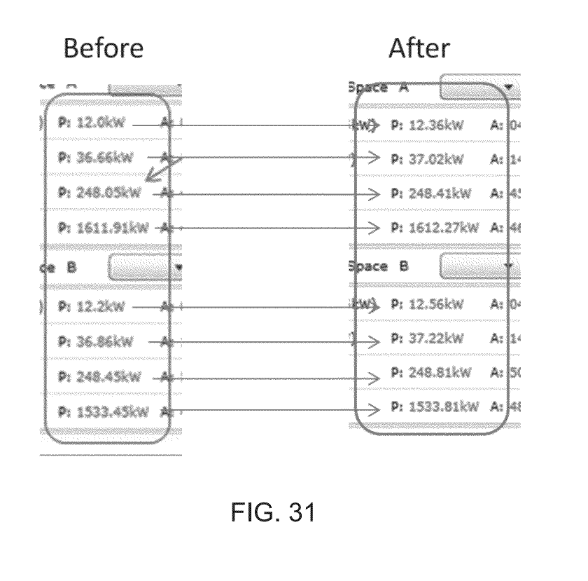

The consumption is not only seen at the virtual space, it rolls up thru the entire set of power distribution components that participate in providing power to this virtual space. FIG. 31 provides a before and after view of this virtual space's power chain consumption.

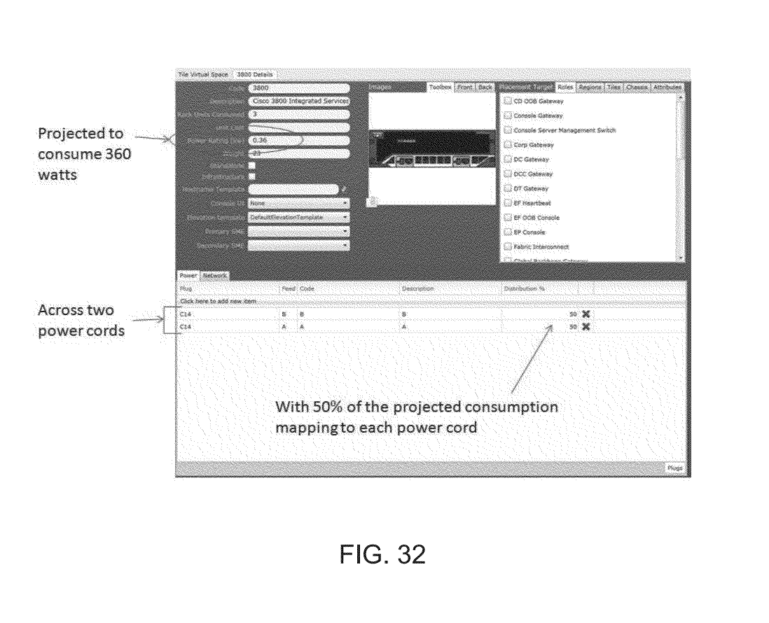

Each device in a “Device Catalogue” feature is configured to define its projected consumption characteristics. The appropriate number of power cords associated with the device is created, and then the projected consumption is split across the defined power cords by setting a percent of the total for each cord. FIG. 32 captures the details of ISR (FIG. 27) as defined in the Device Catalogue.

The above description is intended by way of example only.

What is claimed is:

1. A method comprising:
in a power distribution chain comprising hierarchically arranged low-level and higher level components, obtaining characteristics representing the consumption of power, at a phase-level, of one or more of the low-level components;
based on the obtained characteristics, determining the power consumption, at the phase-level, for each of a plurality of the higher-level components;
based on the power consumption determined for each of the plurality of higher-level components, determining, at the one or more low-level components, a global power consumption, at the phase-level, for the entire power distribution chain; and
displaying the global power consumption, at the phase-level, with reference to the one or more low-level components.

2. The method of claim 1, further comprising:
displaying a representation of the power distribution chain.

3. The method of claim 2, wherein displaying the representation of the power distribution chain comprises:
displaying a forest of expandable trees.

4. The method of claim 1, wherein determining the global power consumption, at the phase-level, for the entire power distribution chain comprises determining a projected global power consumption.

5. The method of claim 1, wherein determining the global power consumption, at the phase-level, for the entire power distribution chain comprises determining a maximum global power consumption.

6. The method of claim 1, wherein determining the global power consumption, at the phase-level, for the entire power distribution chain comprises determining an actual global power consumption.

7. The method of claim 1, further comprising:
configuring one or more pieces of equipment in the data center based on the global power consumption.

8. The method of claim 1, further comprising:
time stamping the obtained characteristics; and
analyzing the obtained characteristics to identify patterns of consumption over time.

9. The method of claim 1, wherein the power distribution chain is configured to distribute facility power phases to at least one component in the power distribution chain, and wherein the at least one component is configured to distribute equipment power phases to one or more pieces of equipment, and wherein the method further comprises:
mapping the facility power phases to the equipment phases at the at least one component.

10. The method of claim 9, further comprising:
reconfiguring at least one of the facility power phases or the equipment phases to change the mapping at the at least one component.

11. One or more computer readable storage media encoded with software comprising computer executable instructions and when the software is executed operable to:
in a power distribution chain comprising hierarchically arranged low-level and higher level components, obtain characteristics representing the consumption of power, at a phase-level, of one or more of the low-level components;
based on the obtained characteristics, determine the power consumption, at the phase-level, for each of a plurality of the higher-level components;
based on the power consumption determined for each of the plurality of higher-level components, determine, at the one or more low-level components, a global power consumption, at the phase-level, for the entire power distribution chain; and
display the global power consumption, at the phase-level, with reference to the one or more low-level components.

12. The computer readable storage media of claim 11, further comprising instructions operable to:
display a representation of the power distribution chain.

13. The computer readable storage media of claim 12, wherein the instructions operable to display the representation of the power distribution chain comprise instructions operable to:
display a forest of expandable trees.

14. The computer readable storage media of claim 11, wherein the instructions operable to determine the global power consumption, at the phase-level, for the entire power distribution chain comprise instructions operable to determine a projected global power consumption.

15. The computer readable storage media of claim 11, wherein the instructions operable to determine the global power consumption, at the phase-level, for the entire power distribution chain comprise instructions operable to determine a maximum global power consumption.

16. The computer readable storage media of claim 11, wherein the instructions operable to determine the global power consumption, at the phase-level, for the entire power distribution chain comprise instructions operable to determine an actual global power consumption.

17. The computer readable storage media of claim 11, further comprising instructions operable to:
time stamp the obtained characteristics; and
analyze the obtained characteristics to identify patterns of consumption over time.

18. The computer readable storage media of claim 11, wherein the power distribution chain is configured to distribute facility power phases to at least one component in the power distribution chain, and wherein the at least one component is configured to distribute equipment power phases to one or more pieces of equipment, and wherein the computer readable storage media further comprises instructions operable to:
map the facility power phases to the equipment phases at the at least one component.

19. An apparatus comprising:
a user interface unit;
a memory storing a data center infrastructure management application; and
a processor configured to, in a power distribution chain comprising hierarchically arranged low-level and higher level components, obtain characteristics representing the consumption of power, at a phase-level, of one or more of the low-level components; based on the obtained characteristics, determine the power consumption, at the phase-level, for each of a plurality of the higher-level components; based on the power consumption determined for each of the plurality of higher-level components, determine, at the one or more low-level components, a global power consumption, at the phase-level, for the entire power distribution chain; and display the global power consumption, at the phase-level, with reference to the one or more low-level components on the user interface unit.

20. The apparatus of claim 19, wherein the processor is configured to display a representation of the power distribution chain.

21. The apparatus of claim 20, wherein the representation of the power distribution chain comprises a forest of expandable trees.

22. The apparatus of claim 19, wherein the processor is configured to determine a projected global power consumption, at the phase-level, for the entire power distribution chain.

23. The apparatus of claim 19, wherein the processor is configured to determine a maximum global power consumption, at the phase-level, for the entire power distribution chain.

24. The apparatus of claim 19, wherein the processor is configured to determine an actual global power consumption, at the phase-level, for the entire power distribution chain.

25. The apparatus of claim 19, wherein the processor is further configured to time stamp the obtained characteristics; and analyze the obtained characteristics to identify patterns of consumption over time.

26. The apparatus of claim 19, wherein the power distribution chain is configured to distribute facility power phases to at least one component in the power distribution chain, and wherein the at least one component is configured to distribute equipment power phases to one or more pieces of equipment, and wherein the processor is configured to map the facility power phases to the equipment phases at the at least one component.
